(19) United States
(12) Patent Application Publication
(10) Pub. No.: US 2025/0280678 A1
(43) Pub. Date: Sep. 4, 2025

(54) DISPLAY DEVICE, DISPLAY PANEL AND VEHICLE

(71) Applicant: LG Display Co., Ltd., Seoul (KR)

(72) Inventor: MinJi KANG, Paju-si (KR)

(73) Assignee: LG Display Co., Ltd., Seoul (KR)

(21) Appl. No.: 19/041,714

(22) Filed: Jan. 30, 2025

(30) Foreign Application Priority Data
Feb. 29, 2024 (KR) 10-2024-0030226

(51) Int. Cl. H10K 59/131

(52) U.S. Cl. CPC H10K 59/131

(57) ABSTRACT

A display device, a display panel, and a vehicle are discussed. The display device can include comprise a substrate including a display area and a non-display area, a first pad area disposed in the non-display area, an align mark disposed to be spaced apart from the first pad area, and a structure disposed adjacent to the align mark.

### CROSS-REFERENCE TO RELATED APPLICATION

This application claims priority to Korean Patent Application No. 10-2024-0030226, filed in the Republic of Korea on Feb. 29, 2024, the entire contents of which are hereby expressly incorporated by reference into the present application.

### BACKGROUND

### Technical Field

Various embodiments of the disclosure relate to a display device, a display panel and a vehicle, more particularly, for example, without limitation, to a display device, a display panel and a vehicle capable of preventing or minimizing cracks from occurring or propagating in the display panel.

### Description of Related Art

The growth of the intelligent society leads to a rapid advance in display devices for displaying images. Accordingly, display devices are being developed to have a lightweight and slim form factor and excellent performance along with low power consumption.

Various display devices such as liquid crystal displays (LCDs), field emission displays (FEDs), and organic light emitting displays (OLEDs) are recently being utilized.

The description provided in the description of the related art section should not be assumed to be prior art merely because it is mentioned in or associated with the description of the related art section. The description of the related art section can include information that describes one or more aspects of the subject technology, and the description in this section does not limit the disclosure.

### SUMMARY OF THE DISCLOSURE

The inventor of the present application has recognized that a display device can include a display panel having a display area and a non-display area. A chip or a printed circuit board can be disposed in the non-display area of the display panel. When the chip or printed circuit board is coupled to the display panel, a bonding process can be performed.

When the bonding process is performed, a crack can occur in the display panel. When a crack occurs, the crack can propagate into the display panel or moisture can penetrate along the crack. Further, various lines can be damaged by the propagation of crack.

A crack in the display panel can deteriorate the reliability of the display device.

Example embodiments of the disclosure can provide a display device capable of preventing or minimizing cracks from occurring or propagating in the display panel.

Example embodiments of the disclosure can provide a display device capable of preventing or minimizing moisture from penetrating due to cracks.

Example embodiments of the disclosure can provide a display device capable of preventing various lines from being damaged by cracks.

Example embodiments of the disclosure can provide a display device capable of mitigating reliability degradation of the display device due to cracks.

A display device according to example embodiments of the disclosure can comprise a substrate including a display area and a non-display area, a first pad area disposed in the non-display area, an align mark disposed to be spaced apart from the first pad area, and a structure disposed adjacent to the align mark.

A display device according to example embodiments of the disclosure can comprise a substrate including a display area and a non-display area, a plurality of insulation layers disposed on the substrate, a pad electrode disposed on the substrate and including a plurality of metal layers, an align mark disposed on the substrate and adjacent to the pad electrode, and a structure disposed on the substrate and including a plurality of metal layers. The structure can be disposed between the pad electrode and the align mark.

According to example embodiments of the disclosure, provided is a display panel provided with a display area and a non-display area, the display panel comprising: a first pad area disposed in the non-display area; an align mark disposed to be spaced apart from the first pad area; and a structure disposed adjacent to the align mark.

According to example embodiments of the disclosure, provided is a display panel, comprising: a plurality of insulation layers; a pad electrode disposed among the plurality of insulation layers and including a plurality of metal layers; an align mark disposed among the plurality of insulation layers and adjacent to the pad electrode; and a structure disposed among the plurality of insulation layers and including a plurality of metal layers, wherein the structure is disposed between the pad electrode and the align mark.

According to example embodiments of the disclosure, there can be provided a display device with enhanced reliability.

According to example embodiments of the disclosure, there can be provided a display device capable of preventing or minimizing cracks from occurring or propagating in the display panel by providing a structure in an insulation layer of the display panel.

According to example embodiments of the disclosure, there can be provided a display device with enhanced anti-moisture permeability by preventing or minimizing cracks from occurring or propagating in the display panel.

According to example embodiments of the disclosure, there can be provided a display device capable of preventing or minimizing damage to various lines by preventing or minimizing cracks from occurring or propagating in the display panel.

According to example embodiments of the disclosure, there can be provided a display device capable of low power consumption by enhancing the lifetime of the display device by preventing or minimizing cracks from occurring or propagating in the display panel.

It is to be understood that both the foregoing general description and the following detailed description are examples and explanatory, and are intended to provide further explanation of the inventive concepts as claimed.

### BRIEF DESCRIPTION OF THE DRAWINGS

The accompanying drawings, which are included to provide a further understanding of the disclosure, are incorporated in and constitute a part of this disclosure, illustrate aspects and embodiments of the disclosure and together with the description serve to explain principles of the disclosure. The above and other objects, features, and advantages of the disclosure will be more clearly understood from the following detailed description, taken in conjunction with the accompanying drawings, in which:

FIG. 1 is a view illustrating a system configuration of a display device according to example embodiments of the disclosure;

FIG. 2 illustrates a display panel according to an example embodiment of the disclosure;

FIG. 3 is an example cross-sectional view illustrating a display panel according to example embodiments of the disclosure;

FIG. 4 is an example plan view illustrating a display device according to example embodiments of the disclosure;

FIG. 5 is an example view illustrating area X of FIG. 4;

FIG. 6 is an example cross-sectional view taken along line A-B of FIG. 5;

FIG. 7 is an example view illustrating area X of FIG. 4; and

FIG. 8 is an example cross-sectional view taken along line C-D of FIG. 7.

Throughout the drawings and the detailed description, unless otherwise described, the same drawing reference numerals should be understood to refer to the same elements, features, and structures. The relative size and depiction of these elements can be exaggerated for clarity, illustration, and convenience.

### DETAILED DESCRIPTION OF THE EMBODIMENTS

Reference will now be made in detail to embodiments of the present disclosure, examples of which can be illustrated in the accompanying drawings. The progression of processing steps and/or operations described is an example; however, the sequence of steps and/or operations is not limited to that set forth herein and can be changed as is known in the art, with the exception of steps and/or operations necessarily occurring in a particular order. Names of the respective elements used in the following explanations can be selected only for convenience of writing the specification and can be thus different from those used in actual products.

In the following description of examples or embodiments of the disclosure, reference will be made to the accompanying drawings in which it is shown by way of illustration specific examples or embodiments that can be implemented, and in which the same reference numerals and signs can be used to designate the same or like components even when they are shown in different accompanying drawings from one another. Further, in the following description of examples or embodiments of the disclosure, detailed descriptions of well-known functions and components incorporated herein will be omitted when it is determined that the description can make the subject matter in some embodiments of the disclosure rather unclear. The terms such as “include,” “have,” “comprise,” “contain,” “constitute,” “make up of,” “formed of,” and “consist of” used herein are generally intended to allow other components to be added unless the terms are used with the term “only”. As used herein, singular forms are intended to include plural forms unless the context clearly indicates otherwise.

The shape, size, ratio, angle, number and the like shown in the drawings to illustrate the embodiments of the present disclosure are only for illustration and are not limited to the contents shown in the drawings. Wherever possible, the same reference numbers will be used throughout the drawings to refer to the same or like parts. In the following description, detailed descriptions of technologies or configurations related to the present disclosure can be omitted so as not to unnecessarily obscure the subject matter of the present disclosure.

The shapes, sizes, dimensions (e.g., length, width, height, thickness, radius, diameter, area, etc.), ratios, angles, numbers of elements, and the like illustrated in the accompanying drawings for describing the example embodiments of the present disclosure are merely examples, and the present disclosure is not limited thereto. Like reference numerals generally denote like elements throughout the specification.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

In describing a variety of embodiments of the present disclosure, when terms for positional relationship such as “on”, “above”, “over”, “below”, “under”, “beside”, “beneath”, “near”, “close to,” “adjacent to”, “on a side of”, “next” are used, at least one intervening element can be present between two elements unless “immediately” or “directly” is used.

Spatially relative terms, such as “under,” “below,” “beneath”, “lower,” “over,” “upper” and the like, can be used herein for ease of description to describe one element or feature's relationship to another element(s) or feature(s) as illustrated in the figures. It will be understood that the spatially relative terms can encompass different orientations of an element in use or operation in addition to the orientation depicted in the figures. For example, if an element in the figures is inverted, elements described as “below” or “beneath” other elements or features would then be oriented “over” the other elements or features. Thus, the example term “below” can encompass both an orientation of below and above. Similarly, the example term “above” or “over” can encompass both an orientation of “above” and “below”.

When an element or layer is disposed “on” another element or layer, another layer or another element can be interposed directly on the other element or therebetween.

Terms, such as “first”, “second”, “A”, “B”, “(A)”, or “(B)” can be used herein to describe elements of the disclosure. Each of these terms is not used to define essence, order, sequence, or number of elements etc., but is used merely to distinguish the corresponding element from other elements.

When it is mentioned that a first element “is connected or coupled to”, “contacts or overlaps” etc. a second element, it should be interpreted that, not only can the first element “be directly connected or coupled to” or “directly contact or overlap” the second element, but a third element can also be “interposed” between the first and second elements, or the first and second elements can “be connected or coupled to”, “contact or overlap”, etc. each other via a fourth element. Here, the second element can be included in at least one of two or more elements that “are connected or coupled to”, “contact or overlap”, etc. each other.

When time relative terms, such as “after,” “subsequent to,” “next,” “before,” and the like, are used to describe processes or operations of elements or configurations, or flows or steps in operating, processing, manufacturing methods, these terms can be used to describe non-consecutive or non-sequential processes or operations unless the term “directly” or “immediately” is used together.

The term “at least one” should be understood as including all possible combinations which can be suggested from one or more relevant items. For example, the meaning of “at least one of a first item, a second item, or a third item” can be each one of the first item, the second item, or the third item and also be all possible combinations that can be suggested from two or more of the first item, the second item, and the third item.

In addition, when any dimensions, relative sizes etc. are mentioned, it should be considered that numerical values for an elements or features, or corresponding information (e.g., level, range, etc.) include a tolerance or error range that can be caused by various factors (e.g., process factors, internal or external impact, noise, etc.) even when a relevant description is not specified. Further, the term “can” fully encompasses all the meanings of the term “may”.

A term “device” used herein can refer to a display device including a display panel and a driver for driving the display panel. Examples of the display device can include a light emitting element, and the like. In addition, examples of the device can include a notebook computer, a television, a computer monitor, an automotive device, a wearable device, and an automotive equipment device, and a set electronic device (or apparatus) or a set device (or apparatus), for example, a mobile electronic device such as a smartphone or an electronic pad, which are complete products or final products respectively including light emitting element and the like, but embodiments of the present disclosure are not limited thereto.

The respective features of various embodiments according to the present disclosure can be partially or entirely joined or combined and technically variably related or operated, and the embodiments can be implemented independently or in combination.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning for example consistent with their meaning in the context of the relevant art and should not be interpreted in an idealized or overly formal sense unless expressly so defined herein.

In the aspects of the present disclosure, a source electrode and a drain electrode are distinguished from each other, for convenience of description. However, the source electrode and the drain electrode are used interchangeably. The source electrode can be the drain electrode, and the drain electrode can be the source electrode. Also, the source electrode in any one aspect of the present disclosure can be the drain electrode in another aspect of the present disclosure, and the drain electrode in any one aspect of the present disclosure can be the source electrode in another aspect of the present disclosure.

All the components of each device or apparatus according to all embodiments of the present disclosure are operatively coupled and configured.

In the specification, in adding reference numerals for elements in each drawing, it should be noted that like reference numerals already used to denote like elements in other drawings are used for elements wherever possible. In addition, the dimension scales of constituent elements shown in the drawings can be different from actual dimension scales, for convenience of description. That is, the dimension scales of constituent elements shown in the drawings should not be interpreted to be the same as those shown in the drawings.

In the aspects of the present disclosure, a source electrode and a drain electrode are distinguished from each other, for convenience of description. However, the source electrode and the drain electrode are used interchangeably. The source electrode can be the drain electrode, and the drain electrode can be the source electrode. Also, the source electrode in any one aspect of the present disclosure can be the drain electrode in another aspect of the present disclosure, and the drain electrode in any one aspect of the present disclosure can be the source electrode in another aspect of the present disclosure.

Hereinafter, various embodiments of the disclosure are described in detail with reference to the accompanying drawings.

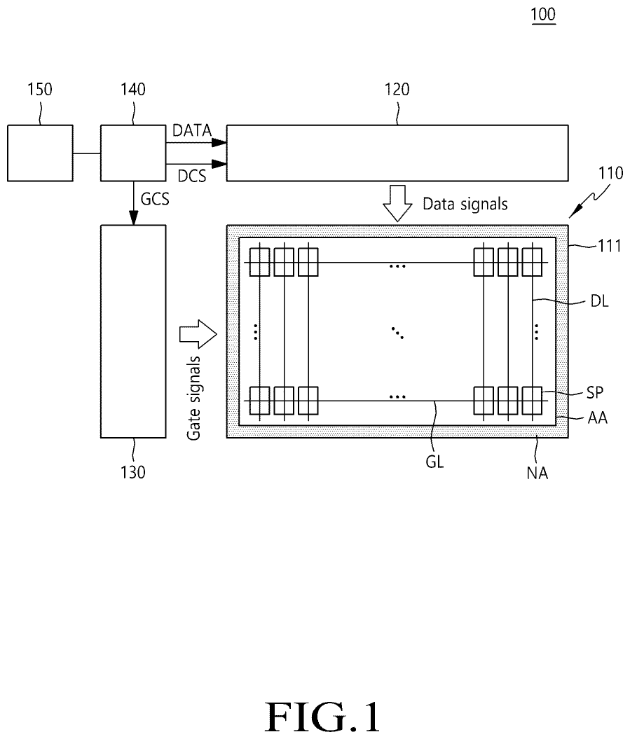

FIG. 1 is a view illustrating a system configuration of a display device according to example embodiments of the disclosure;

Referring to FIG. 1, a display device 100 according to example embodiments of the disclosure can include a display panel 110 and display driving circuits, as components for displaying images. The display driving circuit can be a circuit for driving the display panel 110. The display driving circuits can include a data driving circuit 120, a gate driving circuit 130, and a controller 140, but example embodiments of the disclosure are not limited thereto.

The display panel 110 can include a substrate 111 and a plurality of subpixels SP disposed on the substrate 111.

The substrate 111 can include a display area (active area) AA capable of displaying an image and a non-display area (non-active area) NA positioned around or outside the display area AA.

A plurality of subpixels SP for image display can be disposed in the display area AA. The non-display area NA can include a pad area PA positioned at at least one side of the display area AA in a column direction.

In the display panel 110 according to example embodiments of the disclosure, the non-display area NA can be very small. In the disclosure, the non-display area NA can also be referred to as a “bezel.” For example, the non-display area NA can include a first non-display area, a second non-display area, a third non-display area, and a fourth non-display area. The first non-display area can be positioned outside the display area AA in the column direction. The second non-display area can be positioned outside the display area AA in the row direction. The third non-display area can be positioned outside the display area AA in the column direction and can be positioned opposite to the first non-display area. The fourth non-display area can be positioned outside the display area AA in the row direction and can be positioned opposite to the second non-display area. The first non-display area among the first to fourth non-display areas can include a pad area where the data driving circuit is connected or bonded. Among the first to fourth non-display areas, the second to fourth non-display areas including no pad area can have a very small size, but example embodiments of the disclosure are not limited thereto.

As another example, the boundary area between the display area AA and the non-display area NA can be bent so that the non-display area NA can be positioned under the display area AA. In this case, no or little change can be made to the non-display area NA shown to the user when the user views the display area 100 from the front, but example embodiments of the disclosure are not limited thereto.

Various types of signal lines for driving a plurality of subpixels SP can be disposed on the substrate 111 of the display panel 110.

The display device 100 according to example embodiments of the disclosure can be a liquid crystal display device or a self-emission display device in which the display panel 110 emits light by itself, but example embodiments of the disclosure are not limited thereto. When the display device 100 according to the example embodiments of the disclosure is a self-emission display device, each of the plurality of subpixels SP can include a light emitting element.

For example, the display device 100 according to example embodiments of the disclosure can be an organic light emitting diode display device in which the light emitting element is implemented as an organic light emitting diode (OLED). As another example, the display device 100 according to example embodiments of the disclosure can be an inorganic light emitting display device in which the light emitting element is implemented as an inorganic material-based light emitting diode. As another example, the display device 100 according to example embodiments of the disclosure can be a quantum dot display device in which the light emitting element is implemented as a quantum dot which is self-emission semiconductor crystal. As another example, the display device 100 according to example embodiments of the disclosure can be a micro LED display device or a mini LED display device.

Each of the plurality of subpixels SP is a minimum unit which configures the display area and n subpixels SP form one pixel. Each of the plurality of subpixels SP can emit light having different wavelengths from each other. The plurality of subpixels can include first to third subpixels which emit different color light from each other. Each pixel P can be divided into a red subpixel, a green subpixel, and a blue subpixel, for color rendering. Each pixel P can further include a white subpixel. The plurality of subpixels SP can be variously modified in colors and configurations, as necessary. However, the present disclosure is not limited thereto.

For example, the plurality of subpixels SP can include red, green, and blue subpixels, in which the red, green, and blue subpixels can be disposed in a repeated manner. Alternatively, the plurality of subpixels SP can include red, green, blue, and white subpixels, in which the red, green, blue, and white subpixels can be disposed in a repeated manner, or the red, green, blue, and white subpixels can be disposed in a quad type. For example, the red sub pixel, the blue sub pixel, and the green sub pixel can be sequentially disposed along a row direction, or the red sub pixel, the blue sub pixel, the green sub pixel and the white sub pixel can be sequentially disposed along the row direction. However, in the embodiment of the present disclosure, the color type, disposition type, and disposition order of the subpixels are not limiting, and can be configured in various forms according to light-emitting characteristics, device lifespans, and device specifications.

Meanwhile, the subpixels can have different light-emitting areas according to light-emitting characteristics. For example, a subpixel that emits light of a color different from that of a blue subpixel can have a different light-emitting area from that of the blue subpixel. For example, the red subpixel, the blue subpixel, and the green subpixel, or the red subpixel, the blue subpixel, the white subpixel, and the green subpixel can each has a different light-emitting area.

The structure of each of the plurality of subpixels SP can vary according to the type of the display device 100. For example, when the display device 100 is a self-emission display device in which the subpixels SP emit light by themselves, each subpixel SP can include a light emitting element that emits light by itself, one or more transistors, and one or more capacitors, but example embodiments of the disclosure are not limited thereto.

For example, various types of signal lines can include a plurality of data lines DL transferring data signals (also referred to as data voltages or image signals) and a plurality of gate lines GL transferring gate signals (also referred to as scan signals).

The plurality of data lines DL and the plurality of gate lines GL can cross each other. Each of the plurality of data lines DL can be disposed to extend in the column direction. Each of the plurality of gate lines GL can be disposed to extend in the row direction. According to example embodiments of the disclosure, the column direction and the row direction can be relative directions. In other words, the column direction can be the row direction depending on the viewpoint, and the row direction can be the column direction depending on the viewpoint. For convenience of description, described below is an example in which each of the plurality of data lines DL is disposed in the column direction, and each of the plurality of gate lines GL is disposed in the row direction, but example embodiments of the disclosure are not limited thereto. For example, each of the plurality of data lines DL can be disposed in the row direction, and each of the plurality of gate lines GL can be disposed in the column direction. In example embodiments of the disclosure, the angle between the row direction and the column direction can be 90 degrees or can an angle different from 90 degrees. Further, in example embodiments of the disclosure, the row direction can be referred to as a first direction, and the column direction can be referred to as a second direction. Alternatively, the column direction can be referred to as a first direction, and the row direction can be referred to as a second direction.

The data driving circuit 120 can be a circuit for driving a plurality of data lines DL. The data driving circuit 120 can output data signals to the plurality of data lines DL. The gate driving circuit 130 can be a circuit for driving a plurality of gate lines GL, and can supply gate signals to the plurality of gate lines GL.

The data driving circuit 120 can receive digital image data DATA from the controller 140 and can convert the received image data DATA into analog data signals and output them to the plurality of data lines DL.

For example, the data driving circuit 120 can be connected with the display panel 110 by a tape automated bonding (TAB) method or connected to a bonding pad of the display panel 110 by a chip on glass (COG) or chip on panel (COP) method or can be implemented by a chip on film (COF) method and connected with the display panel 110, but example embodiments of the disclosure are not limited thereto.

The data driving circuit 120 can be connected to one side (e.g., an upper or lower side) of the display panel 110. As another example, depending on the driving scheme or the panel design scheme, data driving circuits 120 can be connected with both the sides (e.g., both the upper and lower sides) of the display panel 110, or two or more of the four sides of the display panel 110.

The data driving circuit 120 can be connected outside the display area AA of the display panel 110, but as another example, the data driving circuit 120 can be disposed in the display area AA of the display panel 110.

The gate driving circuit 130 is a circuit for driving the plurality of gate lines GL, and can output gate signals to the plurality of gate lines GL.

The gate driving circuit 130 can receive a first gate voltage corresponding to a turn-on level voltage and a second gate voltage corresponding to a turn-off level voltage, along with various gate driving control signals GCS, generate gate signals, and supply the generated gate signals to the plurality of gate lines GL.

In the display device 100 according to example embodiments of the disclosure, the gate driving circuit 130 can be embedded, in a gate in panel (GIP) type, in the display panel 110, but example embodiments of the disclosure are not limited thereto. When the gate driving circuit 130 is of the gate in panel type, the gate driving circuit 130 can be formed on the substrate 111 of the display panel 110 during the manufacturing process of the display panel 110.

For example, the gate driving circuit 130 can be disposed in the non-display area NA of the display panel 110.

As another example, the gate driving circuit 130 can be disposed in the display area AA of the display panel 110. For example, the gate driving circuit 130 can be disposed in a first partial area in the display area AA (e.g., a left area or a right area in the display area AA). As another example, the gate driving circuit 130 can be disposed in a first partial area in the display area AA (e.g., a left area or right area in the display area AA) and a second partial area (e.g., a right area or left area in the display area AA).

In the disclosure, the gate driving circuit 130 embedded in the display panel 110 in a gate-in-panel type can also be referred to as a “gate-in-panel circuit.” The gate driving circuit 130 can be disposed on the substrate 111, or connected to the substrate 111.

The controller 140 is a device for controlling the data driving circuit 120 and the gate driving circuit 130 and can control driving timings for the plurality of data lines DL and driving timings for the plurality of gate lines GL.

The controller 140 can supply a data driving control signal DCS to the data driving circuit 120 to control the data driving circuit 120 and can supply a gate driving control signal GCS to the gate driving circuit 130 to control the gate driving circuit 130.

The controller 140 can receive input image data from the host system 150 and supply image data DATA to the data driving circuit 120 based on the input image data.

The controller 140 can be implemented as a separate component from the data driving circuit 120, or the controller 140 and the data driving circuit 120 can be integrated into an integrated circuit (IC). However, the present disclosure is not limited thereto.

The controller 140 can be a timing controller used in display technology, a control device that can perform other control functions as well as the functions of the timing controller, or a control device other than the timing controller, or can be a circuit in the control device. The controller 140 can be implemented as various circuits or electronic components, such as an integrated circuit (IC), a field programmable gate array (FPGA), an application specific integrated circuit (ASIC), or a processor, but is not limited thereto.

The controller 140 can be mounted on a printed circuit board or a flexible printed circuit and can be electrically connected with the data driving circuit 120 and the gate driving circuit 130 through the printed circuit board or the flexible printed circuit.

The controller 140 can transmit/receive signals to/from the data driving circuit 120 according to one or more predetermined interfaces. The interface can include, e.g., a low voltage differential signaling (LVDS) interface, an embedded clock point-point interface (EPI), and a serial peripheral interface (SPI), but example embodiments of the disclosure are not limited thereto. Similarly, the controller 140 can transmit signals to, and receive signals from, the gate driving circuit 130 via one or more predefined interfaces.

To provide a touch sensing function as well as an image display function, the display device 100 according to example embodiments of the disclosure can include a touch sensor and a touch sensing circuit that senses the touch sensor to detect whether a touch occurs by a touch object, such as a finger or pen, or the position of the touch.

The touch sensing circuit can include a touch driving circuit that drives and senses the touch sensor and generates and outputs touch sensing data and a touch controller that can detect an occurrence of a touch or the position of the touch using touch sensing data.

The touch sensor can include a plurality of touch electrodes. The touch sensor can further include a plurality of touch lines for electrically connecting the plurality of touch electrodes and the touch driving circuit.

The touch sensor can be present in a touch panel form outside the display panel 110 or can be present inside the display panel 110. When the touch sensor, in the form of a touch panel, exists outside the display panel 110, the touch sensor is of an external type. When the touch sensor is of the external type, the touch panel and the display panel 110 can be separately manufactured or can be combined during an assembly process. The external-type touch panel can include a touch panel substrate and a plurality of touch electrodes on the touch panel substrate.

When the touch sensor is present inside the display panel 110, the touch sensor can be formed on the substrate, together with signal lines and electrodes related to display driving, during the manufacturing process of the display panel 110.

The touch driving circuit can supply a touch driving signal to at least one of the plurality of touch electrodes and can sense at least one of the plurality of touch electrodes to generate touch sensing data.

The touch sensing circuit can perform touch sensing in a self-capacitance sensing scheme or a mutual-capacitance sensing scheme.

When the touch sensing circuit performs touch sensing in the self-capacitance sensing scheme, the touch sensing circuit can perform touch sensing based on capacitance between each touch electrode and the touch object (e.g., finger or pen). According to the self-capacitance sensing scheme, each of the plurality of touch electrodes can serve both as a driving touch electrode and as a sensing touch electrode. The touch driving circuit can drive all or some of the plurality of touch electrodes and sense all or some of the plurality of touch electrodes.

When the touch sensing circuit performs touch sensing in the mutual-capacitance sensing scheme, the touch sensing circuit can perform touch sensing based on capacitance between the touch electrodes. According to the mutual-capacitance sensing scheme, the plurality of touch electrodes are divided into driving touch electrodes and sensing touch electrodes. The touch driving circuit can drive the driving touch electrodes and sense the sensing touch electrodes.

The touch driving circuit and the touch controller included in the touch sensing circuit can be implemented as separate devices or as a single device. The touch driving circuit and the data driving circuit can be implemented as separate devices or as a single device.

The display device 100 can further include a power supply circuit for supplying various types of power to the display driver integrated circuit and/or the touch sensing circuit. The power supply circuit can supply power voltages and various other voltages related to display driving to the display driving circuit or display panel 110.

The display device 100 according to example embodiments of the disclosure can be a mobile terminal, such as a smart phone or a tablet, or a monitor or television (TV) in various sizes but, without limited thereto, can also be a display in various types and various sizes capable of displaying information or images.

The display device 100 according to example embodiments of the disclosure can further include an electronic device such as a camera (image sensor), a detection sensor, or the like. For example, the detection sensor can be a sensor that detects an object or a human body by receiving light such as infrared rays, ultrasonic waves, or ultraviolet rays, but example embodiments of the disclosure are not limited thereto.

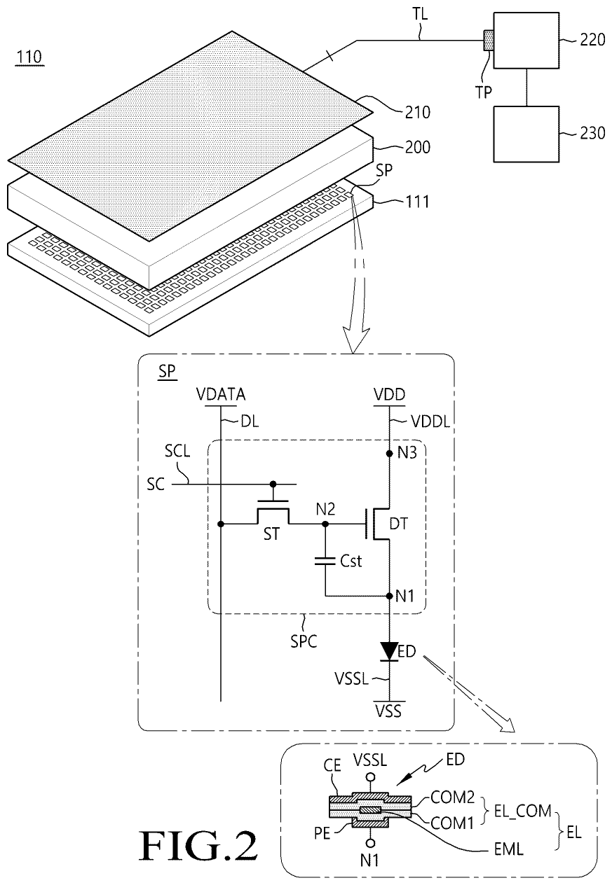

FIG. 2 is a view illustrating a display panel according to an example embodiment of the disclosure.

Referring to FIG. 2, the display panel 110 can include a substrate 111 provided with a plurality of subpixels SP and an encapsulation layer 200 on the substrate 111. The encapsulation layer 200 can also be referred to as an encapsulation substrate or an encapsulation portion.

When the display device 100 according to example embodiments of the disclosure is a self-luminous display device, each of the plurality of subpixels SP disposed on the substrate 111 can include a light emitting element ED and a subpixel circuit SPC for driving the light emitting element ED.

The subpixel circuit SPC can include a plurality of transistors and at least one capacitor for driving the light emitting element ED, but example embodiments of the disclosure are not limited thereto. In the disclosure, the subpixel circuit SPC can drive the light emitting element ED by supplying a driving current to the light emitting element ED at a predetermined timing. The light emitting element ED can be driven by a driving current to emit light.

The plurality of transistors can include a driving transistor DT for driving the light emitting element ED and a scan transistor ST that is turned on or off according to the scan signal SC.

The driving transistor DT can supply a driving current to the light emitting element ED.

The scan transistor ST can be configured to control the electrical state of a corresponding node in the subpixel circuit SPC or to control the state or operation of the driving transistor DT.

The at least one capacitor can include a storage capacitor Cst for maintaining a constant voltage during a frame.

To drive the subpixel SP, a data signal VDATA as an image signal and a scan signal SC as a gate signal can be applied to the subpixel SP. Further, for driving the subpixel SP, a common pixel driving voltage including the driving voltage VDD and the base voltage VSS can be applied to the subpixel SP.

The light emitting element ED can include a pixel electrode PE, an intermediate layer EL, and a common electrode CE. The intermediate layer EL can be disposed between the pixel electrode PE and the common electrode CE. For example, the pixel electrode PE can be an electrode disposed in each subpixel SP, and the common electrode CE can be an electrode commonly disposed in all the subpixels SP. For example, the pixel electrode PE can be an anode, and the common electrode CE can be a cathode. As another example, the pixel electrode PE can be a cathode, and the common electrode CE can be an anode. For convenience of description, an example is described in which the pixel electrode PE is an anode, and the common electrode CE is a cathode.

When the light emitting element ED is an organic light emitting element, the intermediate layer EL can include a light emitting layer EML, a first common intermediate layer COM1 between the pixel electrode PE and the light emitting layer EML, and a second common intermediate layer COM2 between the light emitting layer EML and the common electrode CE. The first common intermediate layer COM1 and the second common intermediate layer COM2 can be collectively referred to as a common intermediate layer EL_COM.

The light emitting layer EML can be disposed for each subpixel SP. The common intermediate layer EL_COM can be commonly disposed over the plurality of subpixels SP, but example embodiments of the disclosure are not limited thereto.

The light emitting layer EML can be disposed for each emission area. The common intermediate layer EL_COM can be commonly disposed across a plurality of emission areas and non-emission areas, but example embodiments of the disclosure are not limited thereto.

For example, the first common intermediate layer COM1 can include a hole injection layer HIL, an electron blocking layer EBL, and a hole transport layer HTL, but example embodiments of the disclosure are not limited thereto. The second common intermediate layer COM2 can include an electron transport layer ETL, a hole blocking layer HBL, and an electron injection layer EIL, but example embodiments of the disclosure are not limited thereto.

The hole injection layer can inject holes from the pixel electrode PE to the hole transport layer, the hole transport layer can transport the holes to the light emitting layer EML, the electron injection layer can inject electrons from the common electrode CE to the electron transport layer, and the electron transport layer can transport electrons to the light emitting layer EML.

For example, the common electrode CE can be electrically connected to the base voltage line VSSL. The base voltage VSS, which is one type of the common pixel driving voltage, can be applied to the common electrode CE through the base voltage line VSSL. The pixel electrode PE can be electrically connected directly or indirectly (through another transistor) to the first node N1 of the driving transistor DT of each subpixel SP. In the disclosure, “base voltage VSS” can also be referred to as a “low-potential power voltage” or a “low-potential voltage,” and “base voltage line VSSL” can also be referred to as a “low-potential power voltage line” or a “low-potential voltage line.”

Each light emitting element ED can include portions where the pixel electrode PE, the light emitting layer in the intermediate layer LE, and the common electrode CE overlap. A predetermined light emitting area can be formed by each light emitting element ED. For example, the light emitting area of each light emitting element ED can include an overlapping area of the pixel electrode PE, the intermediate layer EL, and the common electrode CE.

For example, the light emitting element ED can be an organic light emitting diode (OLED), an inorganic light emitting diode (LED), a quantum dot light emitting element, a micro LED, or a mini LED, but example embodiments of the disclosure are not limited thereto. For example, when the light emitting element ED is an organic light emitting diode (OLED), the intermediate layer EL of the light emitting element ED can include an intermediate layer EL including an organic material.

The driving transistor DT can be a driving transistor for supplying a driving current to the light emitting element ED. The driving transistor DT can be connected between a driving voltage line VDDL and the light emitting element ED.

The driving transistor DT can include a first node N1, a second node N2, and a third node N3. The first node N1 can be electrically connected to the light emitting element ED, the second node N2 can receive a data signal VDATA, and the third node N3 can receive a driving voltage VDD from the driving voltage line VDDL. The driving transistor DT can be connected to the first node N1 and the third node N3.

In the driving transistor DT, the second node N2 can be a gate node, the first node N1 can be a source node or a drain node, and the third node N3 can be a drain node or a source node. Hereinafter, for convenience of description, an example is described in which in the driving transistor DT, the second node N2 can be a gate node, the first node N1 can be a source node, and the third node N3 can be a drain node, but example embodiments of the disclosure are not limited thereto.

The scan transistor ST included in the subpixel circuit SPC illustrated in FIG. 2 can be a switching transistor for transferring the data signal VDATA, which is an image signal, to the second node N2, which is the gate node of the driving transistor DT.

The scan transistor ST can be controlled to be turned on and off by the scan signal SC, which is a gate signal applied through the scan line SCL, which is a type of the gate line GL, to control electrical connection between the second node N2 of the driving transistor DT and the data line DL. The drain electrode or the source electrode of the scan transistor ST can be electrically connected to the data line DL, the source electrode or the drain electrode of the scan transistor ST can be electrically connected to the second node N2 of the driving transistor DT, and the gate electrode of the scan transistor ST can be electrically connected to the scan line SCL.

The storage capacitor Cst can be electrically connected between the first node N1 and the second node N2 of the driving transistor DT. The storage capacitor Cst can include a first capacitor electrode electrically connected to the first node N1 of the driving transistor DT or corresponding to the first node N1 of the driving transistor DT, and a second capacitor electrode electrically connected to the second node N2 of the driving transistor DT or corresponding to the second node N2 of the driving transistor DT.

The capacitor Cst can be an external capacitor intentionally designed to be outside the driving transistor DT, but not a parasite capacitor (e.g., Cgs or Cgd) which is an internal capacitor that can be present between the first node N1 and the second node N2 of the driving transistor DT, but example embodiments of the disclosure are not limited thereto.

Each of the driving transistor DT and the scan transistor ST can be an n-type transistor or a p-type transistor, but example embodiments of the disclosure are not limited thereto. For example, one of the driving transistor DT and the scan transistor ST can be either an n-type transistor or a p-type transistor.

The display panel 110 can have a top emission structure or a bottom emission structure.

When the display panel 110 has a top emission structure, at least a portion of the subpixel circuit SPC can overlap at least a portion of the light emitting element ED in a vertical direction. Accordingly, the area of the light emitting area can increase and the aperture ratio can increase.

When the display panel 110 has a bottom emission structure, the subpixel circuit SPC may not overlap the light emitting element ED in the vertical direction.

The subpixel circuit SPC can have a 2T (Transistor) 1C (Capacitor) structure including two transistors DT and ST and one capacitor Cst. In some cases, the subpixel circuit SPC can further include one or more transistors or can further include one or more capacitors.

For example, the subpixel circuit SPC can have an 8T1C structure including 8 transistors and 1 capacitor. As another example, the subpixel circuit SPC can have a 6T2C structure including 6 transistors and 2 capacitors. As another example, the subpixel circuit SPC can have a 7T1C structure including 7 transistors and 1 capacitor. Example embodiments of the disclosure are not limited thereto.

The transistors can be thin-film transistors TFTs. Active layers of the thin-film transistors TFTs can be formed of a semiconductor material, such as an oxide semiconductor, amorphous semiconductor, or polycrystalline semiconductor, but is not limited thereto.

The oxide semiconductor material can have an excellent effect of preventing or minimizing a leakage current and relatively inexpensive manufacturing cost. The oxide semiconductor can be made of a metal oxide such as zinc (Zn), indium (In), gallium (Ga), tin (Sn), and titanium (Ti) or a combination of a metal such as zinc (Zn), indium (In), gallium (Ga), tin (Sn), or titanium (Ti) and its oxide. Specifically, the oxide semiconductor can include zinc oxide (ZnO), zinc-tin oxide (ZTO), zinc-indium oxide (ZIO), indium oxide (InO), titanium oxide (TiO), indium-gallium-zinc oxide (IGZO), indium-zinc-tin oxide (IZTO), indium zinc oxide (IZO), indium gallium tin oxide (IGTO), and indium gallium oxide (IGO), but is not limited thereto.

The polycrystalline semiconductor material has a fast movement speed of carriers such as electrons and holes and thus has high mobility, and has low energy power consumption and superior reliability. The polycrystalline semiconductor can be made of polycrystalline silicon (poly-Si), but is not limited thereto.

The amorphous semiconductor material can be made of amorphous silicon (a-Si), but is not limited thereto.

Depending on the structure of the subpixel circuit SPC, the type and number of gate lines or the gate signals supplied to the subpixel SP can vary. Further, the type and the number of common pixel driving voltages supplied to the subpixel SP can vary according to the structure of the subpixel circuit SPC.

Since the circuit elements (e.g., the light emitting element ED implemented as an organic light emitting diode (OLED) including an organic material) in each subpixel SP are vulnerable to external moisture or oxygen, the encapsulation layer 200 can be disposed on the display panel 110. The encapsulation layer 200 can prevent external moisture or oxygen from penetrating into circuit elements (e.g., the light emitting element ED). The encapsulation layer 200 can be configured in various forms so that the light emitting elements ED do not contact moisture or oxygen. For example, the encapsulation layer 200 can be constituted of two or more layers in which organic films and inorganic films are alternately stacked, but example embodiments of the disclosure are not limited thereto.

The display device 100 according to example embodiments of the disclosure can include a touch sensor layer 210 including a plurality of sensor electrodes to sense the user's touch, a touch driving circuit 220 configured to sense the plurality of sensor electrodes, and a touch controller 230 configured to determine the presence or absence of a touch or touch coordinates using the sensing result (touch sensing data) of the touch driving circuit 220.

The touch sensor layer 210 can be embedded in the display panel 110. For example, the touch sensor layer 210 can be disposed on the encapsulation layer 200 in the display panel 110. The touch sensor layer 210 can be a touch portion.

The display panel 110 can further include a plurality of touch pads TP electrically connected to the touch driving circuit 220 and a plurality of touch routing lines for electrically connecting the plurality of sensor electrodes included in the touch sensor layer 210 to the plurality of touch pads TP connected to the touch driving circuit 220.

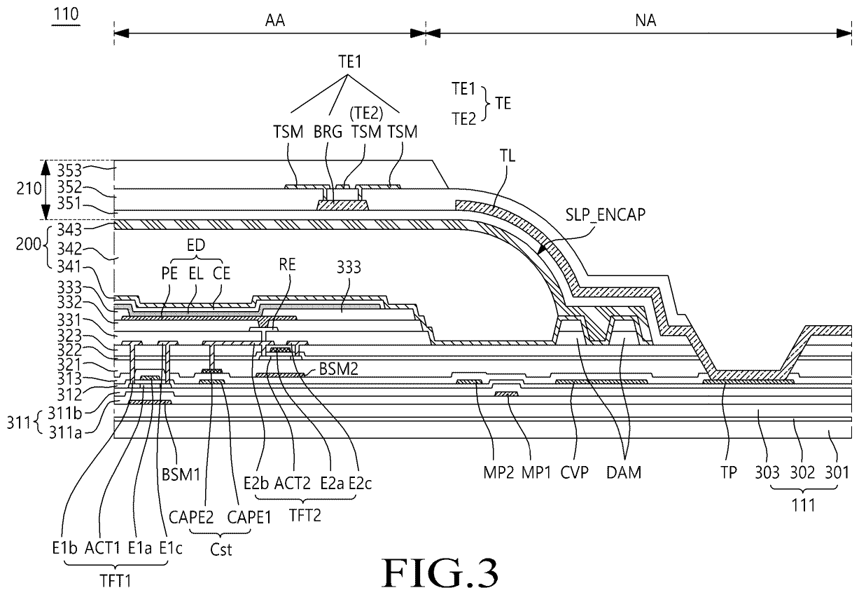

FIG. 3 is a cross-sectional view illustrating a display panel according to example embodiments of the disclosure.

Referring to FIG. 3, the display panel 110 according to example embodiments of the disclosure can include a transistor portion, a light emitting element portion, and an encapsulation portion, but example embodiments of the disclosure are not limited thereto.

The substrate 111 can include a single layer or multiple layers. For example, the substrate 111 can include a flexible polymer film. For example, the flexible polymer film can be made of any one of polyimide (PI), polyethylene terephthalate (PET), acrylonitrile-butadiene-styrene copolymer (ABS), polymethyl methacrylate (PMMA), polyethylene naphthalate (PEN), polycarbonate (PC), polyethersulfone (PES), polyarylate (PAR), polysulfone (PSF), cyclic olefin copolymer (COC), triacetylcellulose (TAC), polyvinyl alcohol (PVA), and polystyrene (PS), and the present disclosure is not limited thereto. When the substrate 111 includes multiple layers, the substrate 111 can include a first substrate 301, an intermediate layer 302, and a second substrate 303. The intermediate layer 302 can be positioned between the first substrate 301 and the second substrate 303. For example, each of the first substrate 301 and the second substrate 303 can be a polyimide (PI) layer, but example embodiments of the disclosure are not limited thereto. The intermediate layer 302 can be an inorganic insulation layer, but example embodiments of the disclosure are not limited thereto. When an electric charge is charged to the first substrate PI1 which is a polyimide layer, the intermediate layer 302 can prevent the electric charge from affecting transistors disposed on the second substrate 303 through the second substrate 303 which is a polyimide layer.

Further, the intermediate layer 302 can prevent a moisture component from penetrating upward through the first substrate 301. For example, the intermediate layer 302 can be formed of a single layer of silicon nitride (SiNx) or silicon oxide (SiOx) or multiple layers thereof, or can be formed of a double layer of silicon dioxide (SiO₂) and silicon nitride (SiNx), but is not limited thereto.

The transistor portion can include a substrate 111, an insulation layer 311, 312, 313, 321, 322, and 323 on the substrate 111, thin film transistors TFT1 and TFT2, a storage capacitor Cst, and various electrodes or signal lines.

The thin film transistors TFT1 and TFT2 included in the transistor portion can include a first thin film transistor TFT1 and a second thin film transistor TFT2.

The first thin film transistor TFT1 can include a first active layer ACT1, a first electrode E1a, a second electrode E1b, and a third electrode E1c. The first active layer ACT1 can be a first semiconductor layer, but example embodiments of the disclosure are not limited thereto. For example, the first active layer ACT1 can be formed of an oxide semiconductor, amorphous silicon, polysilicon, or low temperature polysilicon (LTPS), but example embodiments of the disclosure are not limited thereto. The first thin film transistor TFT1 can be implemented as a p-channel thin film transistor or an n-channel thin film transistor, but example embodiments of the disclosure are not limited thereto.

The first electrode E1a can be a gate electrode, the second electrode E1b can be a source electrode or a drain electrode, and the third electrode E1c can be a drain electrode or a source electrode. Hereinafter, for convenience of description, the first electrode E1a is referred to as a first gate electrode E1a, the second electrode E1b is referred to as a first source electrode E1b, and the third electrode E1c is referred to as a first drain electrode E1c, but example embodiments of the disclosure are not limited thereto.

The second thin film transistor TFT2 can include a second active layer ACT2, a fourth electrode E2a, a fifth electrode E2b, and a sixth electrode E2c. The second active layer ACT2 can be a second semiconductor layer, but example embodiments of the disclosure are not limited thereto. For example, the second active layer ACT2 can be formed of an oxide semiconductor, amorphous silicon, polysilicon, or low temperature polysilicon (LTPS), but example embodiments of the disclosure are not limited thereto. The second thin film transistor TFT2 can be implemented as a p-channel thin film transistor or an n-channel thin film transistor, but example embodiments of the disclosure are not limited thereto.

For example, one of the first thin film transistor TFT1 and the second thin film transistor TFT2 can include an oxide semiconductor as an active layer. As another example, one of the first thin film transistor TFT1 and the second thin film transistor TFT2 can use low-temperature polysilicon as an active layer. As another example, the first thin film transistor TFT1 and the second thin film transistor TFT2 can be configured with an oxide semiconductor as an active layer. As another example, the first thin film transistor TFT1 and the second thin film transistor TFT2 can be configured with low-temperature polysilicon as an active layer. As another example, of the first thin film transistor TFT1 and the second thin film transistor TFT2, the driving transistor DT can be configured with an oxide semiconductor as an active layer, and the scan transistor ST can be configured with low-temperature polysilicon as an active layer. As another example, of the first thin film transistor TFT1 and the second thin film transistor TFT2, the driving transistor DT can be configured with low-temperature polysilicon as an active layer, and the scan transistor ST can be configured with an oxide semiconductor as an active layer. As another example, a transistor included in a gate driving circuit 140 of a gate in panel (GIP) type can be configured with an oxide semiconductor or low-temperature polysilicon as an active layer. As another example, all the transistors configured on the substrate 111 and transistors included in a gate driving circuit 130 of a gate in panel (GIP) type can be configured with an oxide semiconductor as an active layer.

The fourth electrode E2a can be a gate electrode, the fifth electrode E2b can be a source electrode or a drain electrode, and the sixth electrode E2c can be a drain electrode or a source electrode. Hereinafter, for convenience of description, the fourth electrode E2a is referred to as a second gate electrode E2a, the fifth electrode E2b is referred to as a second source electrode E2b, and the sixth electrode E2c is referred to as a second drain electrode E2c. However, example embodiments of the disclosure are not limited thereto.

The second active layer ACT2 of the second thin film transistor TFT2 can be positioned higher from the substrate 111 than the first active layer ACT1 of the first thin film transistor TFT1.

The first buffer layer 311 can be disposed under the first active layer ACT1 of the first thin film transistor TFT1, and a second buffer layer 321 can be disposed under the second active layer ACT2 of the second thin film transistor TFT2. For example, the first active layer ACT1 of the first thin film transistor TFT1 can be positioned on the first buffer layer 311, and the second active layer ACT2 of the second thin film transistor TFT2 can be positioned on the second buffer layer 321. The second buffer layer 321 can be positioned higher than the first buffer layer 311.

For example, the first buffer layer 311 can be formed by inorganic film in a single layer or in multiple layers, for example, the inorganic film in a single layer can be a silicon oxide (SiOx) film or a silicon nitride (SiNx) film, and inorganic films in multiple layers can formed by alternately stacking one or more silicon oxide (SiOx) films, one or more silicon nitride (SiNx) films, and one or more amorphous silicon (a-Si), but the present disclosure is not limited thereto. However, the first buffer layer 311 can be excluded in accordance with the structure or properties of the display device.

For example, the second buffer layer 321 can be formed by inorganic film in a single layer or in multiple layers, for example, the inorganic film in a single layer can be a silicon oxide (SiOx) film or a silicon nitride (SiNx) film, and inorganic films in multiple layers can formed by alternately stacking one or more silicon oxide (SiOx) films, one or more silicon nitride (SiNx) films, and one or more amorphous silicon (a-Si), but the present disclosure is not limited thereto. However, the second buffer layer 321 can be excluded in accordance with the structure or properties of the display device.

The storage capacitor Cst can be disposed in various metal layers in the display panel 110. For example, the storage capacitor Cst can include a first capacitor electrode CAPE1 and a second capacitor electrode CAPE2.

The light emitting element portion can include a plurality of light emitting elements ED disposed on at least one planarization layer 331 and 332. Each of the plurality of light emitting elements ED can include a pixel electrode PE, an intermediate layer EL, and a common electrode CE. However, the present disclosure is not limited thereto.

The encapsulation portion can include an encapsulation layer 200 on the plurality of light emitting elements ED. The encapsulation layer 200 can be a single layer or multiple layers, but example embodiments of the disclosure are not limited thereto. The encapsulation portion can further include a dam DAM in addition to the encapsulation layer 200.

Hereinafter, a structure, for example a vertical structure of the display panel 110 according to example embodiments of the disclosure is described in more detail with reference to FIG. 3.

Referring to FIG. 3, the first buffer layer 311 can be disposed on the substrate 111. The first buffer layer 311 can be a single layer or multiple layers, but example embodiments of the disclosure are not limited thereto. When the first buffer layer 311 includes multiple layers, the first buffer layer 311 can include a first sub buffer layer 311a and a second sub buffer layer 311b.

The first active layer ACT1 of the first thin film transistor TFT1 can be disposed on the first buffer layer 311. The first active layer ACT1 can include a channel area in which a channel is formed, a source connection area on one side of the channel area, and a drain connection area on the other side of the channel area.

The first insulation layer 312 can be disposed on the first active layer ACT1 of the first thin film transistor TFT1. The first gate electrode E1a of the first thin film transistor TFT1 can be disposed on the first insulation layer 312. The second insulation layer 313 can be disposed on the first gate electrode E1a of the first thin film transistor TFT1. The first insulation layer 312 can be a gate insulation layer, but example embodiments of the disclosure are not limited thereto. The first insulation layer 312 can be formed as a single layer made of an inorganic material or a multilayer made of different inorganic materials. For example, the first insulation layer 312 can be formed as a single layer of any one of a silicon oxide (SiOx) film, a silicon nitride (SiNx) film, and a silicon oxynitride (SiON) film, or a multilayer thereof. For example, the first insulation layer 312 can be formed by inorganic film in a single layer or in multiple layers, for example, the inorganic film in a single layer can be a silicon oxide (SiOx) film, a silicon nitride (SiNx) film or silicon oxynitride (SiON) film, and inorganic films in multiple layers can formed by alternately stacking at least one of one or more silicon oxide (SiOx) films, one or more silicon nitride (SiNx) films and one or more silicon oxynitride (SiON) films, and one or more amorphous silicon (a-Si), but the present disclosure is not limited thereto. The second insulation layer 313 can be an interlayer insulation layer, but example embodiments of the disclosure are not limited thereto. The second insulation layer 313 can be formed as a single layer made of an inorganic material or a multilayer made of different inorganic materials. For example, the second insulation layer 313 can be formed as a single layer of any one of a silicon oxide (SiOx) film, a silicon nitride (SiNx) film, and a silicon oxynitride (SiON) film, or a multilayer thereof. For example, the second insulation layer 313 can be formed by inorganic film in a single layer or in multiple layers, for example, the inorganic film in a single layer can be a silicon oxide (SiOx) film, a silicon nitride (SiNx) film or silicon oxynitride (SiON) film, and inorganic films in multiple layers can formed by alternately stacking at least one of one or more silicon oxide (SiOx) films, one or more silicon nitride (SiNx) films and one or more silicon oxynitride (SiON) films, and one or more amorphous silicon (a-Si), but the present disclosure is not limited thereto.

The second buffer layer 321 can be disposed on the second insulation layer 313.

The second active layer ACT2 of the second thin film transistor TFT2 can be disposed on the second buffer layer 321. The second active layer ACT2 can include a channel area in which a channel is formed, a source connection area on one side of the channel area, and a drain connection area on the other side of the channel area.

The third insulation layer 322 can be disposed on the second active layer ACT2 of the second thin film transistor TFT2. The second gate electrode E2a of the second thin film transistor TFT2 can be disposed. The fourth insulation layer 323 can be disposed on the second gate electrode E2a of the second thin film transistor TFT2. The third insulation layer 322 can be a gate insulation layer, but example embodiments of the disclosure are not limited thereto. The third insulation layer 322 can be formed as a single layer made of an inorganic material or a multilayer made of different inorganic materials. For example, the third insulation layer 322 can be formed as a single layer of any one of a silicon oxide (SiOx) film, a silicon nitride (SiNx) film, and a silicon oxynitride (SiON) film, or a multilayer thereof. For example, the third insulation layer 322 can be formed by inorganic film in a single layer or in multiple layers, for example, the inorganic film in a single layer can be a silicon oxide (SiOx) film, a silicon nitride (SiNx) film or silicon oxynitride (SiON) film, and inorganic films in multiple layers can formed by alternately stacking at least one of one or more silicon oxide (SiOx) films, one or more silicon nitride (SiNx) films and one or more silicon oxynitride (SiON) films, and one or more amorphous silicon (a-Si), but the present disclosure is not limited thereto. The fourth insulation layer 323 can be an interlayer insulation layer, but example embodiments of the disclosure are not limited thereto. The fourth insulation layer 323 can be formed as a single layer made of an inorganic material or a multilayer made of different inorganic materials. For example, the fourth insulation layer 323 can be formed as a single layer of any one of a silicon oxide (SiOx) film, a silicon nitride (SiNx) film, and a silicon oxynitride (SiON) film, or a multilayer thereof. For example, the fourth insulation layer 323 can be formed by inorganic film in a single layer or in multiple layers, for example, the inorganic film in a single layer can be a silicon oxide (SiOx) film, a silicon nitride (SiNx) film or silicon oxynitride (SiON) film, and inorganic films in multiple layers can formed by alternately stacking at least one of one or more silicon oxide (SiOx) films, one or more silicon nitride (SiNx) films and one or more silicon oxynitride (SiON) films, and one or more amorphous silicon (a-Si), but the present disclosure is not limited thereto.

The first source electrode E1b and the first drain electrode E1c of the first thin film transistor TFT1, and the second source electrode E2b and the second drain electrode E2c of the second thin film transistor TFT2 can be disposed on the fourth insulation layer 323.

The first source electrode E1b and the first drain electrode E1c of the first thin film transistor TFT1 can be connected to the source connection area and the drain connection area, of the first active layer ACT1, respectively, through holes of the fourth insulation layer 323, the third insulation layer 322, the second buffer layer 321, the second insulation layer 313, and the first insulation layer 312.

The second source electrode E2b and the second drain electrode E2c of the second thin film transistor TFT2 can be connected to the source connection area and the drain connection area, of the second active layer ACT2, respectively, through the holes of the fourth insulation layer 323 and the third insulation layer 322.

The first source electrode E1b and the first drain electrode E1c of the first thin film transistor TFT1, and the second source electrode E2b and the second drain electrode E2c of the second thin film transistor TFT2 can include a first metal and can be disposed in the first metal layer. Here, the first metal and the first metal layer can be referred to as a first source-drain metal and a first source-drain metal layer.

Referring to FIG. 3, e.g., the storage capacitor Cst can be formed by a first capacitor electrode CAPE1 and a second capacitor electrode CAPE2. In some cases, the storage capacitor Cst can be formed by three or more capacitor electrodes. In some cases, the storage capacitor Cst can have a form in which two or more capacitors are connected in parallel.

Each of the first capacitor electrode CAPE1 and the second capacitor electrode CAPE2 can be disposed on various metal layers disposed in the display panel 110.

For example, the first capacitor electrode CAPE1 can include the same first gate metal as the first gate electrode E1a of the first thin film transistor TFT1 on the first insulation layer 312 and can be disposed in the first gate metal layer, but example embodiments of the disclosure are not limited thereto. For example, the first capacitor electrode CAPE1 and the first gate electrode E1a of the first thin film transistor TFT1 can be disposed on different layers; for example, the first capacitor electrode CAPE1 and the first gate electrode E1a of the first thin film transistor TFT1 can include different materials.

For example, the second capacitor electrode CAPE2 can be disposed on the second insulation layer 313.

The second source electrode E2b of the second thin film transistor TFT2 can be electrically connected to the second capacitor electrode CAPE2 through holes of the fourth insulation layer 323, the third insulation layer 322, and the second buffer layer 321.

For example, the first thin film transistor TFT1 can be the scan transistor ST of FIG. 2, and the second thin film transistor TFT2 can be the driving transistor DT of FIG. 2.

The transistor portion can further include metal layers MP1 and MP2. For example, the first metal layer MP1 can be disposed between the first sub buffer layer 311a and the second sub buffer layer 311b included in the first buffer layer 311, but example embodiments of the disclosure are not limited thereto. The second metal layer MP2 can include the same first gate metal as the first gate electrode E1a of the first thin film transistor TFT1, and can be disposed in the first gate metal layer, but example embodiments of the disclosure are not limited thereto. For example, the second metal layer MP2 and the first gate electrode E1a of the first thin film transistor TFT1 can be formed on different layers; for example, the second metal layer MP2 and the first gate electrode E1a of the first thin film transistor TFT1 can include different materials. The first metal layer MP1 can be a first metal pattern, and the second metal layer MP2 can be a second metal pattern, but example embodiments of the disclosure are not limited thereto. Meanwhile, the first metal layer MP1 and the second metal layer MP2 can include same or different material.

Each of the first metal layer MP1 and the second metal layer MP2 can be disposed in the display area AA or the non-display area NA.

Referring to FIG. 3, the transistor portion can further include a first shield metal BSM1 disposed on the substrate 111. The first shield metal BSMI can overlap the first active layer ACT1 of the first thin film transistor TFT1. The first shield metal BSM1 can be disposed under the first active layer ACT1 of the first thin film transistor TFT1. For example, the first shield metal BSM1 can be disposed between the substrate 111 and the first buffer layer 311, or can be disposed between the first sub buffer layer 311a and the second sub buffer layer 311b.

The transistor portion can further include a second shield metal BSM2 disposed on the substrate 111. The second shield metal BSM2 can overlap the second active layer ACT2 of the second thin film transistor TFT2. The second shield metal BSM2 can be disposed under the second active layer ACT2 of the second thin film transistor TFT2.

For example, the second shield metal BSM2 can be disposed in a metal layer between the second insulation layer 313 and the second buffer layer 321. The second shield metal BSM2 can be disposed in the same metal layer as the second capacitor CAPE2, but example embodiments of the disclosure are not limited thereto.

As another example, the second shield metal BSM2 can be disposed in the same first gate metal layer as the first gate electrode E1a of the first thin film transistor TFT1. Referring to FIG. 3, the transistor portion can further include a common driving voltage layer CVP to which a common driving voltage is applied. For example, the common driving voltage applied to the common driving voltage layer CVP can also be referred to as a power signal, and can be a driving voltage VDD or a base voltage VSS. The driving voltage VDD can be referred to as a high-potential power supply voltage (a high-potential power supply signal or a high-potential voltage), and the base voltage VSS can be referred to as a low-potential power supply voltage (a low-potential power supply signal or a low-potential voltage).

The common driving voltage layer CVP can be disposed in the display area AA or the non-display area NA.

At least one planarization layer can be disposed on the first thin film transistor TFT1 and the second thin film transistor TFT2. In the example of FIG. 3, two planarization layers 331 and 332 are disposed on the first thin film transistor TFT1 and the second thin film transistor TFT2. In some cases, three or more planarization layers can be disposed on the first thin film transistor TFT1 and the second thin film transistor TFT2, but example embodiments of the disclosure are not limited thereto.

The first planarization layer 331 can be disposed on the first source electrode E1b and the first drain electrode E1c of the first thin film transistor TFT1, and the second source electrode E2b and the second drain electrode E2c of the second thin film transistor TFT2. For example, the first planarization layer 331 can be disposed on the first thin film transistor TFT1 and the second thin film transistor TFT2. For example, the first planarization layer 331 can be disposed while covering both the first thin film transistor TFT1 and the second thin film transistor TFT2.

A relay electrode RE can be disposed on the first planarization layer 331. The relay electrode RE can electrically connect the second source electrode E2b of the second thin film transistor TFT2 and the pixel electrode PE.

The relay electrode RE can be electrically connected to the second source electrode E2b of the second thin film transistor TFT2 through the hole of the first planarization layer 331. The second source electrode E2b of the second thin film transistor TFT2 can be electrically connected to the second capacitor electrode CAPE2 of the storage capacitor Cst.

The relay electrode RE can be disposed in the second metal layer on the first planarization layer 331 and can include a second metal. The second metal and the second metal layer can be referred to as a second source-drain metal and a second source-drain metal layer. The second planarization layer 332 can be disposed on the relay electrode RE.

The light emitting element portion can be disposed on the second planarization layer 332. The light emitting element ED can be formed on the second planarization layer 332. The light emitting element ED can include a pixel electrode PE, an intermediate layer EL, and a common electrode CE. The emission area of the light emitting element ED can be formed in an area in which the pixel electrode PE, the intermediate layer EL, and the common electrode CE overlap and contact each other.

The pixel electrode PE can be disposed on the second planarization layer 332. The pixel electrode PE can be electrically connected to the relay electrode RE through the hole of the second planarization layer 332.

A bank 333 can be disposed on the pixel electrode PE. The bank 333 can be disposed at a boundary between the plurality of subpixels SP and suppress a color mixture of light beams from the plurality of subpixels SP. The bank 333 can cover the edge of pixel electrode PE and can be formed to expose a portion of pixel electrode PE. Accordingly, bank 333 can prevent a current from being concentrated at an end of pixel electrode PE so that it is possible to prevent a deterioration of light emitting efficiency. The opening of the bank 333 can expose a portion of the pixel electrode PE to form the emission area. For example, the opening of the bank 333 can overlap a portion of the pixel electrode PE. The bank 333 can be formed of a material including a black pigment, or an organic material such as a benzocyclobutene resin, a polyimide resin, an acrylic resin, or a photosensitive polymer, but example embodiments of the disclosure are not limited thereto. When the bank 333 is formed of a material including a black pigment, a black dye, or the like, it can be a black bank. When the bank 333 is formed of a material including a black pigment or a black dye, light from the outside can be blocked or light reflected from the outside can be blocked, and thus the luminance of the display device can be further enhanced.

The intermediate layer EL of the light emitting element ED can be disposed on a portion of the pixel electrode PE and the bank 333. The common electrode CE can be disposed on the intermediate layer EL.

The encapsulation portion can be disposed on the light emitting element portion and can be positioned on the common electrode CE. The encapsulation portion can include the encapsulation layer 200 formed on the common electrode CE.

The encapsulation layer 200 can prevent moisture or oxygen from penetrating into the light emitting element ED. For example, the encapsulation layer 200 can prevent moisture or oxygen from penetrating into the organic material included in the intermediate layer EL of the light emitting element ED. The encapsulation layer 200 can be formed of a single layer or multiple layers, but example embodiments of the disclosure are not limited thereto.

In an example, the encapsulation layer 200 can include a first encapsulation layer 341, a second encapsulation layer 342, and a third encapsulation layer 343, but example embodiments of the disclosure are not limited thereto. For example, the first encapsulation layer 341 and the third encapsulation layer 343 can include an inorganic layer, and the second encapsulation layer 342 can include an organic layer, but example embodiments of the disclosure are not limited thereto.

The first encapsulation layer 341 and the third encapsulation layer 343 can be formed of an inorganic insulating material enabling low-temperature deposition thereof, such as silicon nitride (SiNx), silicon oxide (SiOx), silicon oxynitride (SiON), or aluminum oxide (Al2O3). Since the first encapsulation layer 341 and the third encapsulation layer 343 are deposited in a low-temperature atmosphere, it can be possible to prevent the light emitting element ED, which is weak against a high-temperature atmosphere, from being damaged in deposition processes for the first encapsulation layer 341 and the third encapsulation layer 343.

The second encapsulation layer 342 can have a buffering function for reducing stress between layers caused by bending of the display device, and can planarize a step between the layers. The second encapsulation layer 342 can be formed on the substrate formed with the first encapsulation layer 341, using a non-photosensitive organic insulating material such as acryl resin, epoxy resin, phenolic resin, polyamide resin, polyimide resin, polyethylene, or silicon oxycarbide (SiOC) or a photosensitive organic insulating material such as photoacryl, without being limited thereto.

Alternatively, the encapsulation layer 200 can include a first inorganic encapsulation layer, a first organic encapsulation layer, a second inorganic encapsulation layer, a second organic encapsulation layer, and a third inorganic encapsulation layer stacked sequentially.

The first inorganic encapsulation layer, the second inorganic encapsulation layer, and the third inorganic encapsulation layer can serve to block the penetration of moisture or oxygen. The first inorganic encapsulation layer, the second inorganic encapsulation layer, and the third inorganic encapsulation layer can be made of an inorganic material, for example, an inorganic material such as silicon nitride (SiNx), silicon oxide (SiOx), or aluminum oxide (AlOx). However, the present disclosure is not limited thereto.

The first organic encapsulation layer is disposed between the first inorganic encapsulation layer and the second inorganic encapsulation layer, and the second organic encapsulation layer is disposed between the second inorganic encapsulation layer and the third inorganic encapsulation layer. The first organic encapsulation layer and the second organic encapsulation layer can each have a larger thickness than each of the first inorganic encapsulation layer, the second inorganic encapsulation layer, and the third inorganic encapsulation layer in order to adsorb or block particles that can be produced during a process of manufacturing the display device. The first organic encapsulation layer and the second organic encapsulation layer can fill cracks that can be formed in the first inorganic encapsulation layer and the second inorganic encapsulation layer. The first organic encapsulation layer and the second organic encapsulation layer can planarize an upper portion of the first inorganic encapsulation layer and an upper portion of the second inorganic encapsulation layer by covering particles on the first inorganic encapsulation layer and the second inorganic encapsulation layer respectively. For example, the first organic encapsulation layer can planarize an upper portion of the first inorganic encapsulation layer by covering particles on the first inorganic encapsulation layer. For example, the second organic encapsulation layer can planarize an upper portion of the second inorganic encapsulation layer by covering particles on the second inorganic encapsulation layer. The first organic encapsulation layer and the second organic encapsulation layer can be made of an organic material, and for example, epoxy polymer, acrylic polymer, or the like can be used. However, the present disclosure is not limited thereto.

Meanwhile, the encapsulation layer 200 is not limited to three or five layers, for example, n layers alternately stacked between inorganic encapsulation layer and organic encapsulation layer (where n is an integer greater than 3) can be included.

The display panel 110 according to example embodiments of the disclosure can have a built-in touch sensor. In this case, the display panel 110 according to example embodiments of the disclosure can include a touch sensor layer 210 formed on the encapsulation layer 200. The touch sensor layer 210 can be a touch portion.

The touch sensor layer 210 can include a plurality of touch electrodes TE, and can include a sensor metal TSM and a bridge metal BRG to form the plurality of touch electrodes TE. In example embodiments of the disclosure, the sensor metal TSM can be referred to as a sensor metal layer TSM, and the bridge metal BRG can be referred to as a bridge metal layer BRG.

The touch sensor layer 210 can further include insulation layers such as a buffer layer 351 on the encapsulation layer 200, an interlayer insulation layer 352 on the buffer layer 351, and a protective layer 353 on the interlayer insulation layer 352. Here, the buffer layer 351 can be omitted.

The bridge metal BRG can be disposed between the buffer layer 351 and the interlayer insulation layer 352. The sensor metal TSM can be disposed between the interlayer insulation layer 352 and the protective layer 353.

Each of the plurality of touch electrodes TE can be formed of a sensor metal TSM. Each of the plurality of touch electrodes TE can be a mesh type electrode having a plurality of openings, but example embodiments of the disclosure are not limited thereto.

The plurality of touch electrodes TE can include a first touch electrode TE1 and a second touch electrode TE2. The sensor metal TSM included in the first touch electrode TE1 can be electrically connected through the bridge metal BRG. For example, the sensor metals TSM spaced apart from each other can be electrically connected by the bridge metal BRG to constitute one first touch electrode TE1.

The bridge metal BRG can be disposed on the buffer layer 351. The interlayer insulation layer 352 can be disposed on the bridge metal BRG. The sensor metal TSM can be disposed on the interlayer insulation layer 352. A portion of the sensor metal TSM can be connected to the corresponding bridge metal BRG through the hole of the interlayer insulation layer 352.

The sensor metal TSM and the bridge metal BRG can be disposed not to overlap the light emitting element ED. The sensor metal TSM and the bridge metal BRG can overlap the bank 333. However, the present disclosure is not limited thereto.

The plurality of sensor metals TSM can constitute one touch electrode TE. The plurality of sensor metals TSM can be disposed in a mesh form and electrically connected to each other. A portion of the sensor metal TSM and another portion of the sensor metal TSM can be electrically connected through the bridge metal BRG to constitute one touch electrode TE.

The protective layer 353 can be disposed on the sensor metal TSM and the bridge metal BRG. The protective layer 353 can be disposed while covering the sensor metal TSM and the bridge metal BRG.

The touch line TL can electrically connect the touch electrode TE and the touch pad TP. The touch line TL can be formed of at least one of the sensor metal TSM and the bridge metal BRG, but example embodiments of the disclosure are not limited thereto. For example, the touch line TL can be formed of a different material from the sensor metal TSM and the bridge metal BRG.

When the display panel 110 is of a type in which the touch sensor is embedded, the touch line TL can extend along the outer inclined surface SLP_ENCAP of the encapsulation layer 200 and can extend beyond the upper portion of the dam DAM to the pad TP in the non-display area NA.

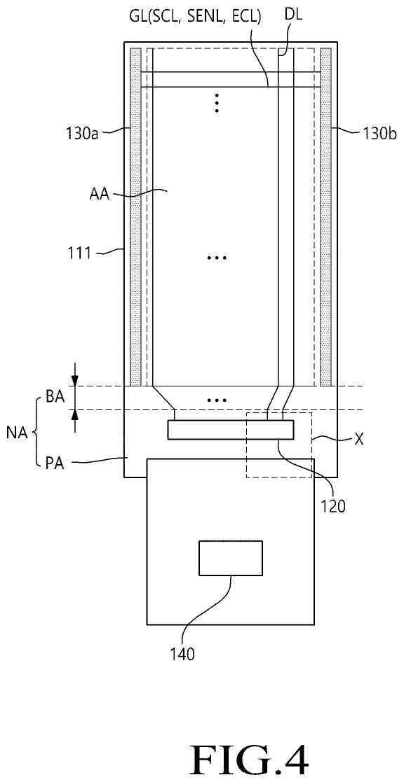

FIG. 4 is an example plan view illustrating a display device 100 according to example embodiments of the disclosure.

Referring to FIG. 4, the substrate 111 can include a display area AA (or active area) and a non-display area NA (or non-active area).

The display area AA can display an image by a plurality of subpixels SP.

The non-display area NA can be around the display area AA or can partially or fully surround the display area AA. The non-display area NA can be an area adjacent to the display area AA. Further, the non-display area NA can be an area disposed adjacent to the display area AA and configured to surround the display area AA. However, the present disclosure is not limited thereto.

For example, the non-display area NA can include a first non-display area located outside the display area AA in a first direction, a second non-display area located outside the display area AA in a second direction intersecting the first direction, a third non-display area located outside the display area AA in the opposite direction to the first direction, and a fourth non-display area located outside the display area AA in the direction opposite to the second direction.

For another example, a boundary area between the display area AA and the non-display area NA can be bent so that the non-display area NA can be located below the display area. In this case, when the user looks at the display device from the front, there can be little or no non-display area NA visible to the user.

The non-display area NA can include a bending area BA and a pad area PA. The bending area BA can be disposed on one side of the display area AA. The pad area PA can be disposed on one side of the bending area BA. The bending area BA can be an area in which the substrate 111 can be bent. The bending area BA can be positioned between the data driving circuit 120 and the display area AA.

The data driving circuit 120 and the gate driving circuits 130a and 130b can be disposed in the non-display area NA.

The data driving circuit 120 can be disposed in the form of a chip on panel (COP) on the substrate 111. The data driving circuit 120 can be electrically connected to the display panel 110 through the data line DL.

The gate driving circuits 130a and 130b can be disposed on the substrate 111. The gate driving circuits 130a and 130b can have a GIP type disposed inside the display panel. The gate driving circuits 130a and 130b can be disposed at the left and right ends of the display area AA on the substrate 111, for example, the gate driving circuit 130a can be disposed at the left end of the display area AA on the substrate 111, and the gate driving circuit 130b can be disposed at the right end of the display area AA on the substrate 111; for example, the gate driving circuit 130a can be disposed at the right end of the display area AA on the substrate 111, and the gate driving circuit 130b can be disposed at the left end of the display area AA on the substrate 111; for example, both of the gate driving circuits 130a and 130b can be disposed at the left or right end of the display area AA on the substrate 111. but example embodiments of the disclosure are not limited thereto.

The gate driving circuits 130a and 130b can be electrically connected to subpixels disposed in the display area AA through the gate line GL. The plurality of gate lines GL can be disposed to cross the plurality of data lines DL, but example embodiments of the disclosure are not limited thereto.

The plurality of gate lines GL can be a scan signal line SCL, a sense signal line SENL, and an emission control line ECL.

When the gate line GL is the scan signal line SCL, the scan signal line SCL can be electrically connected to the gate node of the scan transistor ST illustrated in FIG. 2.

When the gate line GL is the sense signal line SENL, the sense signal line SENL can be electrically connected to the gate node of the sensing transistor. The sensing transistor can be included in the subpixel SP illustrated in FIG. 2, and the sensing transistor can be electrically connected to the first node N1.

When the gate line GL is the emission control line ECL, the emission control line ECL can be electrically connected to the gate node of the emission control transistor. When the subpixel SP is formed of 7T1C, 8T1C, or the like, the emission control transistor can be included in the subpixel SP.

The display controller 140 can be disposed on the printed circuit board PCB. The display controller 140 can control the data driving circuit 120 and the gate driving circuits 130a and 130b. The printed circuit board PCB can be coupled to one end of the substrate 111.

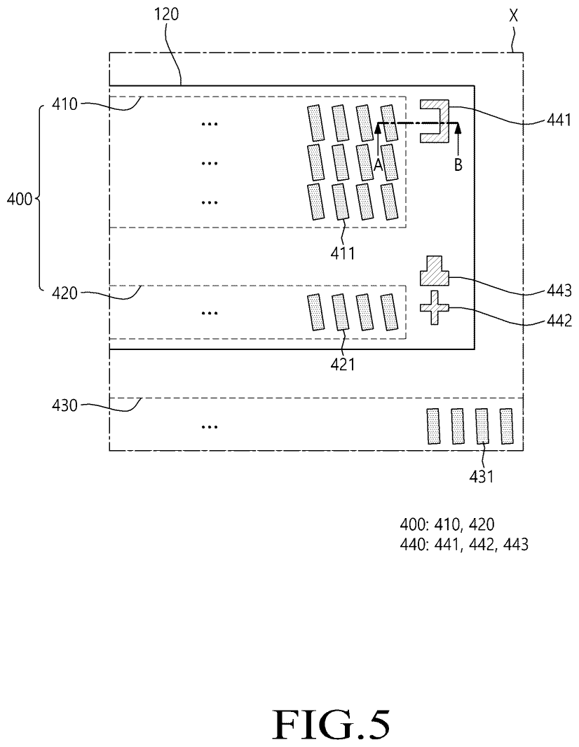

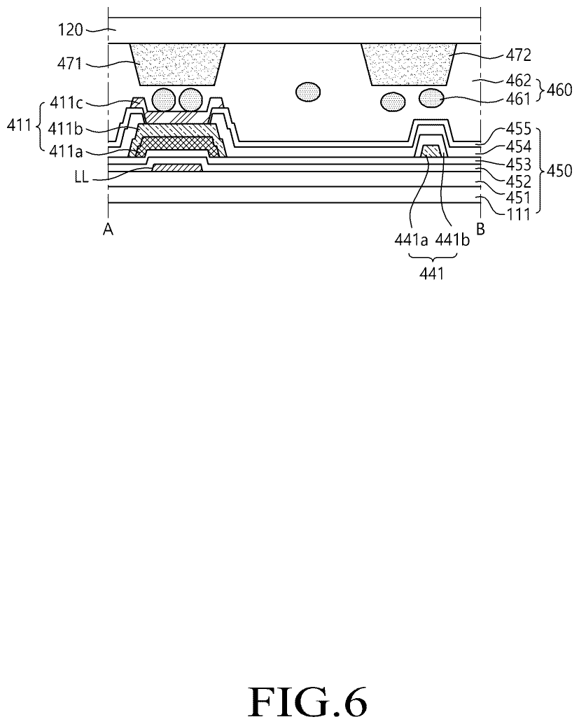

FIG. 5 is an example view illustrating area X of FIG. 4, and FIG. 6 is an example cross-sectional view taken along line A-B of FIG. 5.

Referring to FIG. 5, the pad area PA of the display panel 110 can include a first pad area 400 disposed in the non-display area NA and to which the data driving circuit 120 is bonded, and a second pad area 430 disposed in the non-display area NA and to which the flexible printed circuit is bonded. The first pad area 400 can be disposed between the display area AA and the second pad area 430. The first pad area 400 can be an area disposed in the non-display area NA and to which the data driving circuit 120 is bonded (or attached). The first pad area 400 can be a driving circuit bonding pad area or a driving circuit attachment area, but example embodiments of the disclosure are not limited thereto. The second pad area 430 can be an area disposed in the non-display area NA and to which the flexible printed circuit is bonded (or attached). The second pad area 430 can be a film bonding pad area or a film attachment area, but example embodiments of the disclosure are not limited thereto.

The pad area PA of the display panel 110 can include a first pad area 400 and an align mark 440 disposed to be spaced apart from the first pad area 400.

In the first pad area 400, pad electrodes 411 and 421 through which a signal for driving the display panel 110 is input or output can be disposed. The first pad area 400 can include a first sub pad area 410 and a second sub pad area 420. The first sub pad area 410 can be disposed between the display area AA and the second sub pad area 420.

Pad electrodes 411 through which a signal for driving the display panel is input/output can be disposed in the first sub pad area 410. Pad electrodes 421 through which a signal for driving the display panel is output or input can be disposed in the second sub pad area 420.

The align mark 440 can be disposed to be spaced apart from the first pad area 400 in the row direction, but example embodiments of the disclosure are not limited thereto. The align mark 440 can be used as an identification mark for identifying the position of the data driving circuit 120 or aligning the data driving circuit 120 and the display panel 110 in the process of bonding the data driving circuit 120 and the display panel 110.

The align mark 440 can include a first align mark 441 and a second align mark 442. The first align mark 441 can be disposed to be spaced apart from the first sub pad area 410. The second align mark 442 can be disposed to be spaced apart from the second sub pad area 420. The align mark 440 can include a third align mark 443 disposed between the first align mark 441 and the second align mark 442.

Further, film pad electrodes 431 to which a signal for driving the display panel is input/output can be disposed in the second pad area 430.

The data driving circuit 120 bonded (or attached) to the first pad area 400 can be included. The data driving circuit 120 can be disposed to overlap the first pad area 400 and the align mark 440. The align mark 440 can be disposed inside the edge of the data driving circuit 120, but example embodiments of the disclosure are not limited thereto.

Referring to FIGS. 5 and 6, the pad area PA of the display panel 110 can be disposed on the substrate 111. The pad area PA can include an insulation layer 450, pad electrodes 411 and 412, and an align mark 440.

The insulation layer 450 can be provided with a plurality of insulation layers and can be disposed on the substrate 111. The insulation layer 450 can be a layer formed including an inorganic material.

The insulation layer 450 can include a first insulation layer 451, a second insulation layer 452, a third insulation layer 453, a fourth insulation layer 454, and a fifth insulation layer 455, but example embodiments of the disclosure are not limited thereto. The first insulation layer 451, the second insulation layer 452, the third insulation layer 453, the fourth insulation layer 454, and the fifth insulation layer 455 can be inorganic insulation layers, but example embodiments of the disclosure are not limited thereto.

The first insulation layer 451 can be disposed on the substrate 111. The second insulation layer 452 can be disposed on the first insulation layer 451. The third insulation layer 453 can be disposed on the second insulation layer 452. The fourth insulation layer 454 can be disposed on the third insulation layer 453. The fifth insulation layer 455 can be disposed on the fourth insulation layer 454. For example, the first insulation layer 451, the second insulation layer 452, the third insulation layer 453, the fourth insulation layer 454, and the fifth insulation layer 455 can be formed as a single layer of any one of a silicon oxide (SiOx) film, a silicon nitride (SiNx) film, and a silicon oxynitride (SiON) film, or a multilayer thereof. However, the present disclosure is not limited thereto.

For example, the first insulation layer 451 can correspond to the first buffer layer 311 of FIG. 3 as a buffer layer, but example embodiments of the disclosure are not limited thereto. The second insulation layer 452 can correspond to the second insulation layer 313 of FIG. 3 as an interlayer insulation layer, but example embodiments of the disclosure are not limited thereto. The third insulation layer 453 can correspond to the fourth insulation layer 323 of FIG. 3 as an interlayer insulation layer, but example embodiments of the disclosure are not limited thereto. The fourth insulation layer 454 can correspond to the buffer layer 351 of FIG. 3 as a buffer layer, but example embodiments of the disclosure are not limited thereto. The fifth insulation layer 455 can correspond to the interlayer insulation layer 352 of FIG. 3 as an interlayer insulation layer, but example embodiments of the disclosure are not limited thereto.

A link line LL can be disposed on the first insulation layer 451. The link line LL can be a line for transferring a signal. For example, the link line LL can be a data line, a reference voltage line, or the like, but example embodiments of the disclosure are not limited thereto.

A pad electrode 411 can be disposed on the substrate 111. The pad electrode 411 can be disposed in the pad area PA of the insulation layer 450. The pad electrode 411 can include at least one metal layer. The pad electrode 411 can include a plurality of metal layers. The metal layer can include at least one metal layer.

The pad electrode 411 can include a first metal layer 411a, a second metal layer 411b, and a third metal layer 411c, but example embodiments of the disclosure are not limited thereto. The pad electrode 411 can be formed by disposing or stacking the first metal layer 411a, the second metal layer 411b, and the third metal layer 411c.

The first metal layer 411a can be disposed on the third insulation layer 453. The first metal layer 411a can be disposed to overlap the link line LL. The first metal layer 411a can include the same material as the second electrode E1b and the third electrode E1c of FIG. 3, but example embodiments of the disclosure are not limited thereto. For example, the first metal layer 411a can include a source electrode material and a drain electrode material, but example embodiments of the disclosure are not limited thereto. For example, the first metal layer 411a can be formed together when the second electrode E1b and the third electrode E1c are formed, but example embodiments of the disclosure are not limited thereto. The first metal layer 411a can also include a different material from the second electrode E1b and the third electrode E1c of FIG. 3.

The second metal layer 411b can be disposed on the first metal layer 411a. For example, the second metal layer 411b can be disposed to cover the first metal layer 411a. The second metal layer 411b can be formed of the same material as the relay electrode RE of FIG. 3, but example embodiments of the disclosure are not limited thereto. The second metal layer 411b can be formed together when the relay electrode RE is formed, but example embodiments of the disclosure are not limited thereto. The second metal layer 411b can also be formed of a different material from the relay electrode RE of FIG. 3

The third metal layer 411c can be disposed on the second metal layer 411b. For example, the third metal layer 411c can be formed of the same material as the touch electrode TE, but example embodiments of the disclosure are not limited thereto. The third metal layer 411c can be formed together when the touch electrode TE is formed, but example embodiments of the disclosure are not limited thereto. The third metal layer 411c can also be formed of a different material from the touch electrode TE. The third metal layer 411c can be disposed in an area where portions of the fourth insulation layer 454 and the fifth insulation layer 455 are removed. For example, the third metal layer 411c can contact the second metal layer 411b through contact holes formed in the fourth insulation layer 454 and the fifth insulation layer 455.

The align mark 440 can be disposed on the substrate 111. The align mark 440 can include a first align mark 441, a second align mark 442, and a third align mark 443, but example embodiments of the disclosure are not limited thereto. The cross-sectional structures of the first to third align marks 441, 442, and 443 can be the same, but example embodiments of the disclosure are not limited thereto. Hereinafter, the first align mark 441 is described.

The first align mark 441 can include an eighth metal layer 441a and a first layer 441b, but example embodiments of the disclosure are not limited thereto. The first align mark 441 can be formed by disposing or stacking the eighth metal layer 441a and the first layer 441b.

The eighth metal layer 441a can be disposed on the third insulation layer 453. The eighth metal layer 441a can include the same material as the first metal layer 411a or the second metal layer 441a, but example embodiments of the disclosure are not limited thereto. For example, the eighth metal layer 441a can be formed together when the first metal layer 411a or the second metal layer 411b is formed, but example embodiments of the disclosure are not limited thereto.

The first layer 441b can be disposed on the eighth metal layer 441a. For example, the first layer 441b can be disposed to cover the eighth metal layer 441a. The first layer 441b can be formed of the same material as the first planarization layer 331 or the second planarization layer 332 of FIG. 3, but example embodiments of the disclosure are not limited thereto. The first layer 441b can be formed together when the first planarization layer 331 or the second planarization layer 332 is formed, but example embodiments of the disclosure are not limited thereto.

Referring to FIG. 6, the pad electrode 411 has a structure in which a plurality of metal layers, which are relatively thicker than the align mark 440, are disposed or stacked, and a step difference in which the thickness of the pad electrode 411 is larger than the thickness of the align mark 440 can occur.

The data driving circuit 120 can be disposed on the insulation layer 450.

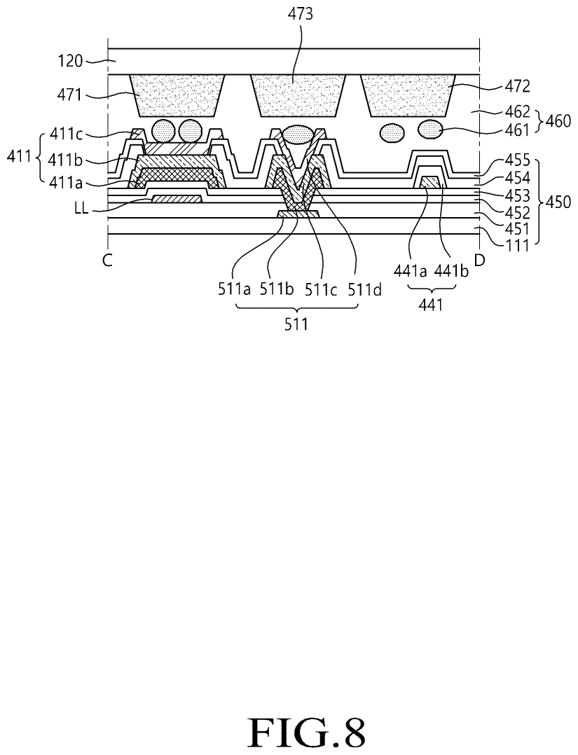

The data driving circuit 120 can be a circuit for driving a plurality of data lines DL. The data driving circuit 120 can include a first bump 471, a second bump 472, and a third bump 473, but example embodiments of the disclosure are not limited thereto. The data driving circuit 120 can include a plurality of bumps, but for convenience of description, the first bump 471 and the second bump 472 are illustrated, but example embodiments of the disclosure are not limited thereto (e.g., see FIG. 8 depicting the first, second and third bumps 471, 472 and 473).

The first bump 471 can be a bump for signal transmission. The first bump 471 can be electrically connected to the pad electrode 411, so that the first bump 471 can supply a signal to the pad electrode 411. The data driving circuit 120 can include at least one first bump 471 electrically connected to the pad electrode 411.

The second bump 472 may not be connected to the pad electrode. The second bump 472 can be a dummy bump, but example embodiments of the disclosure are not limited thereto.

The third bump 473 can be a bump for fixing a position where the data driving circuit 120 is to be coupled to the insulation layer 450. The second bump 472 can be an alignment bump corresponding to the align mark 440, but example embodiments of the disclosure are not limited thereto.

The data driving circuit 120 can be connected to or coupled to the insulation layer 450 by a bonding process. The data driving circuit 120 can be attached to the pad area PA of the insulation layer 450 through an adhesive layer 460. For example, the adhesive layer 460 can be disposed between the insulation layer 450 and the data driving circuit 120. The adhesive layer 460 can include a conductive ball 461 and an adhesive 462, but example embodiments of the disclosure are not limited thereto.

The conductive ball 461 can have a core structure. Further, the conductive ball 461 can have a core-shell structure including a core and a shell surrounding the core, but example embodiments of the disclosure are not limited thereto. In the case of the core structure, the core can be formed of a metal material including at least one of gold (Au), silver (Ag), nickel (Ni), copper (Cu), lead (Pb), and platinum (Pt), but example embodiments of the disclosure are not limited thereto. In the core-shell structure, the core can be formed of resin, and the shell can be formed of a metal material including at least one of gold (Au), silver (Ag), nickel (Ni), copper (Cu), lead (Pb), and platinum (Pt), but example embodiments of the disclosure are not limited thereto.

The adhesive 462 can be an acrylic or silicone adhesive, but example embodiments of the disclosure are not limited thereto. The adhesive 462 can be mixed with the conductive ball 461. The conductive ball 462 can be disposed between the pad electrode 411 and the first bump 471 to electrically connect the pad electrode 411 and the data driving circuit 120. The conductive ball 461 can smoothly transfer a signal between the data driving circuit 120 and the pad electrode 411.

The substrate 111 and the data driving circuit 120 can undergo an attaching (or bonding) process while being pressed at a constant pressure so that the adhesive layer 460 can be evenly attached thereto. In this case, cracks can occur in the insulation layer 450 of the align mark 440, which is thinner than the pad electrode 411. The crack can propagate around the insulation layer 450, damaging the line disposed around the crack. Further, moisture can move along the crack.

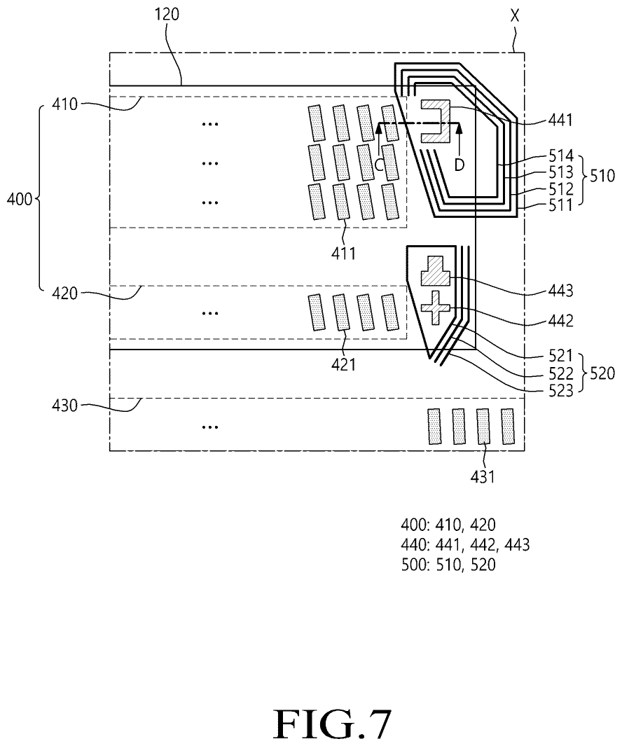

FIG. 7 is an example view illustrating area X of FIG. 4, and FIG. 8 is an example cross-sectional view taken along line C-D of FIG. 7.

The contents of the substrate 111, the pad electrode 411, the insulation layer 450, and the align mark 440 illustrated in FIGS. 7 and 8 can be the same or substantially the same as the contents of the substrate 111, the pad electrode 411, the insulation layer 450, and the align mark 440 illustrated in FIGS. 5 and 6, and thus a redundant description thereof can be omitted or briefly described.

Referring to FIG. 7, the first pad area 400, the structure 500, and the align mark 440 can be disposed in the pad area PA of the display panel 110.

The structure 500 can be disposed adjacent to the align mark 440. A portion of the structure 500 can be disposed between the first pad area 400 and the align mark 440. The structure 500 can be a crack blocker, a crack preventer, or the like, but example embodiments of the disclosure are not limited thereto.

The structure 500 can have different shapes, but example embodiments of the disclosure are not limited thereto. The structure 500 can include main structures and sub structures.

The main structures 511 and 521 can be disposed to surround the align mark 440. The main structures 511 and 521 can be continuously disposed while surrounding the align mark 440. For example, the main structures 511 and 521 can have a seamless closed circuit shape, but example embodiments of the disclosure are not limited thereto.

The sub structures 512, 513, 514, 522, and 523 can surround the align mark 440 and can be disposed to be disconnected or broken in some sections. For example, the sub structures 512, 513, 514, 522, and 523 can have a shape of being disconnected in some sections, but example embodiments of the disclosure are not limited thereto.

The structure 500 can include main structures 511 and 521 and sub structures 512, 513, 514, 522, and 523. The main structures 511 and 521 can surround the align mark 440 and can be continuously disposed. The sub structures 512, 513, 514, 522, and 523 can surround the align mark 440 and can be disposed to be disconnected or broken.

The sub structures 512, 513, and 514 can be disposed inside the main structure 511. Further, the sub structures 522 and 523 can be disposed outside the main structure 521.

The structure 500 can include a first structure 510 and a second structure 520.

The first structure 510 can be disposed adjacent to the first align mark 441. The second structure 520 can be disposed adjacent to the second align mark 442.

The first structure 510 can include a first main structure and a first sub structure. The first main structure can surround the first align mark 441 and can be continuously disposed. The first sub structure can surround the first align mark and can be disposed to be disconnected or broken.

The first structure 510 can include a first main structure 511 and first sub structures 512, 513, and 514. The first main structure 511 can surround the first align mark 441 and can be continuously disposed. The first sub structures 512, 513, and 514 can surround the first align mark 441 and can be disposed to be disconnected or broken.

The second structure 520 can include a second main structure 521 and second sub structures 522 and 523. The second main structure 521 can surround the second align mark 442 and can be continuously disposed. The second sub structures 522 and 523 can surround the second align mark 442 and can be disposed to be disconnected or broken.

The first sub structures 512, 513, and 514 can be disposed inside the first main structure 511. Further, the second sub structures 522 and 523 can be disposed outside the second main structure 521.

The first sub structure can be disposed outside the first main structure, and the second sub structure can be disposed inside the second main structure, but example embodiments of the disclosure are not limited thereto.

Further, pad electrodes 411 and 421 disposed in the first pad area 400 can be included. A portion of the structure 500 can be disposed between the pad electrodes 411 and 421 and the align mark 400.

The pad electrodes 411 and 421 can include a plurality of pad electrodes disposed in a plurality of rows. The align mark 440 can be disposed to be spaced apart from the outermost pad electrode disposed at the end of at least one of the plurality of rows. A portion of the structure 500 can be disposed between the outermost pad electrode and the align mark 400.

A data driving circuit 120 bonded (or attached) to the first pad area 400 can be included. The data driving circuit 120 can be disposed to overlap at least a portion of the first pad area 400, the align mark 440, and the structure 500. For example, the data driving circuit 120 can be disposed on the display panel.

Referring to FIGS. 7 and 8, the pad electrode 411, the align mark 441, and the structure 511 can be disposed in the pad area PA of the display panel 110. The structure 511 can be disposed between the pad electrode 411 and the align mark 441.

Referring to FIG. 8, the structure 511 can include at least one metal layer. The structure 511 can include a plurality of metal layers. The metal layer can include at least one metal layer.

The structure 511 can include a fourth metal layer 511a, a fifth metal layer 511b, a sixth metal layer 511c, and a seventh metal layer 511d. The structure 511 can be formed by disposing or stacking the fourth metal layer 511a, the fifth metal layer 511b, the sixth metal layer 511c, and the seventh metal layer 511d.

The fourth metal layer 511a can be disposed on the substrate 111. The fourth metal layer 511a can include the same material as the first shield metal BSM1 of FIG. 3, but example embodiments of the disclosure are not limited thereto. For example, the fourth metal layer 511a can be formed together when the first shield metal BSM1 is formed, but example embodiments of the disclosure are not limited thereto. The fourth metal layer 511a can also include a different material from the first shield metal BSM1 of FIG. 3.

The fifth metal layer 511b can be disposed on the fourth metal layer 511a. The fifth metal layer 511b can include the same material as the first metal layer 411a, but example embodiments of the disclosure are not limited thereto. For example, the fifth metal layer 511b can be formed together when the first metal layer 411a is formed, but example embodiments of the disclosure are not limited thereto. The fifth metal layer 511b can also include a different material from the first metal layer 411a.

The sixth metal layer 511c can be disposed on the fifth metal layer 511b. For example, the sixth metal layer 511c can be disposed to cover the fifth metal layer 511b. The sixth metal layer 511b can include the same material as the second metal layer 411b, but example embodiments of the disclosure are not limited thereto. For example, the sixth metal layer 511c can be formed together when the second metal layer 411b is formed, but example embodiments of the disclosure are not limited thereto. The sixth metal layer 511b can also include a different material from the second metal layer 411b.

The fifth and sixth metal layers 511b and 511c can be disposed in an area where a portion of the first insulation layer 451, the second insulation layer 452, and the third insulation layer 453 is removed. For example, the fifth metal layer 511b can contact the fourth metal layer 511a through contact holes formed in the first insulation layer 451, the second insulation layer 452, and the third insulation layer 453.

The seventh metal layer 511d can be disposed on the sixth metal layer 511d. For example, the seventh metal layer 511d can be formed of the same material as the third metal layer 411c, but example embodiments of the disclosure are not limited thereto. The seventh metal layer 511d can be formed together when the third metal layer 411c is formed, but example embodiments of the disclosure are not limited thereto. The seventh metal layer 511d can also be formed of a different material from the third metal layer 411c. The seventh metal layer 511d can be disposed in an area where portions of the fourth insulation layer 454 and the fifth insulation layer 455 are removed. For example, the seventh metal layer 511d can contact the sixth metal layer 511c through contact holes formed in the fourth insulation layer 454 and the fifth insulation layer 455.

For example, the structure 511 can be disposed in an area where some of the first to fifth insulation layers 451, 452, 453, 454, and 455 are removed.

The structure 511 can be in an electrically floated state.

The thickness of the structure 511 can be larger than the thickness of the align mark 441 and may not be larger than the thickness of the pad electrode 411. For example, the thickness of the structure 511 can correspond to the thickness of the pad electrode 411.

The data driving circuit 120 can include a first bump 471, a second bump 472, and a third bump 473, but example embodiments of the disclosure are not limited thereto.

The first bump 471 can be electrically connected to the pad electrode 411. The second bump 472 can be disposed to overlap the align mark 411. The third bump 473 can be disposed to overlap the structure 511.

Referring to FIG. 8, the structure 511 can be a structure in which a plurality of metal layers that can be disposed or stacked to have same or substantially the same thickness as the pad electrode 411 are disposed or stacked. When the thickness of the structure 511 is larger than the thickness of the align mark 441 and is not larger than the thickness of the pad electrode 411, the third bump 473 and the structure 511 can maintain the gap between the substrate 111 and the data driving circuit 120 during the bonding process with the data driving circuit 120 to prevent cracks from occurring in the align mark 441.

According to the disclosure, since the structure is formed between the first bump 471 and the second bump 472, it is possible to prevent cracks in the insulation layer 450 caused by the difference in thickness between the first bump 471 and the second bump 472 during the process of attaching the data driving circuit 120 to the first bump 471 and the second bump 472. Accordingly, it is possible to prevent propagation of cracks to the pad area 400 and the link line LL.

Example embodiments of the disclosure can be described as follows.

A display device according to example embodiments of the disclosure can comprise a substrate including a display area and a non-display area, a first pad area disposed in the non-display area, an align mark disposed to be spaced apart from the first pad area, and a structure disposed adjacent to the align mark.

According to example embodiments of the disclosure, the structure can surround the align mark and be continuously disposed.

According to example embodiments of the disclosure, the structure can surround the align mark and be disposed to be disconnected.

According to example embodiments of the disclosure, the structure can include a main structure disposed to surround the align mark, and a sub structure disposed to surround the align mark.

According to example embodiments of the disclosure, the sub structure can be disposed inside the main structure.

According to example embodiments of the disclosure, the sub structure can be disposed outside the main structure.

According to example embodiments of the disclosure, the first pad area can include a first sub pad area and a second sub pad area. The first sub pad area can be disposed between the display area and the second sub pad area.

According to example embodiments of the disclosure, the align mark can include a first align mark disposed to be spaced apart from the first sub pad area. The structure can include a first structure disposed adjacent to the first align mark.

According to example embodiments of the disclosure, the align mark can include a second align mark disposed to be spaced apart from the second sub pad area. The structure can include a second structure disposed adjacent to the second align mark.

According to example embodiments of the disclosure, the first structure can include a first main structure disposed to surround the first align mark, and a first sub structure disposed to surround the first align mark.

According to example embodiments of the disclosure, the second structure can include a second main structure disposed to surround the second align mark, and a second sub structure disposed to surround the second align mark.

According to example embodiments of the disclosure, the first sub structure can be disposed inside the first main structure, and the second sub structure can be disposed outside the second main structure.

According to example embodiments of the disclosure, the first sub structure can be disposed outside the first main structure, and the second sub structure can be disposed inside the second main structure.

According to example embodiments of the disclosure, the align mark can further include a third align mark disposed between the first align mark and the second align mark, and wherein the second structure is disposed adjacent to the third align mark.

According to example embodiments of the disclosure, the second structure can be disposed to surround the second align mark and the third align mark.

According to example embodiments of the disclosure, the display device can further comprise a pad electrode disposed in the first pad area. A portion of the structure can be disposed between the pad electrode and the align mark.

According to example embodiments of the disclosure, the pad electrode can include a plurality of pad electrodes disposed in a plurality of rows. The align mark can be disposed to be spaced apart from an outermost pad electrode disposed at an end of at least one of the plurality of rows. A portion of the structure can be disposed between the outermost pad electrode and the align mark.

According to example embodiments of the disclosure, the display device can further comprise a data driving circuit disposed in the first pad area. The data driving circuit can be disposed to overlap at least a portion of the structure, the align mark, and the first pad area.

According to example embodiments of the disclosure, the display device can further comprise a second pad area disposed in the non-display area. The first pad area can be disposed between the display area and the second pad area.

A display device according to example embodiments of the disclosure can comprise a substrate including a display area and a non-display area, a plurality of insulation layers disposed on the substrate, a pad electrode disposed on the substrate and including a plurality of metal layers, an align mark disposed on the substrate and adjacent to the pad electrode, and a structure disposed on the substrate and including a plurality of metal layers. The structure can be disposed between the pad electrode and the align mark.

According to example embodiments of the disclosure, the pad electrode can include a first metal layer, a second metal layer, and a third metal layer.

According to example embodiments of the disclosure, the structure can include a fourth metal layer, a fifth metal layer, a sixth metal layer, and a seventh metal layer.

According to example embodiments of the disclosure, in the align mark, an eighth metal layer and a first layer can be disposed.

According to example embodiments of the disclosure, the first layer can be disposed to cover the eighth metal layer.

According to the display device according to example embodiments of the disclosure, the eighth metal layer can be formed with same material as the first metal layer or the second metal layer at the same time.

According to the display device according to example embodiments of the disclosure, the plurality of insulation layers can include a first insulation layer disposed on the substrate, a second insulation layer disposed on the first insulation layer, a third insulation layer disposed on the second insulation layer, a fourth insulation layer disposed on the third insulation layer, and a fifth insulation layer disposed on the fourth insulation layer.

According to example embodiments of the disclosure, the pad electrode can be disposed in an area where a portion of the fourth and fifth insulation layers is removed. The structure can be disposed in an area where a portion of the first to fifth insulation layers is removed.

According to example embodiments of the disclosure, the display device can further comprise a link line positioned in an area overlapping the pad electrode and positioned between the first insulation layer and the second insulation layer.

According to example embodiments of the disclosure, the structure can be in an electrically floated state.

According to example embodiments of the disclosure, a thickness of the structure can be larger than a thickness of the align mark and not larger than a thickness of the pad electrode.

According to example embodiments of the disclosure, the thickness of the structure can correspond to the thickness of the pad electrode.

According to example embodiments of the disclosure, the display device can further comprise a data driving circuit disposed on the insulation layer. The data driving circuit can include a first bump electrically connected to the pad electrode.

According to example embodiments of the disclosure, the data driving circuit further can include a second bump disposed to overlap the align mark, and a third bump disposed to overlap the structure.

According to example embodiments of the disclosure, the display device can further comprise an adhesive layer disposed between the insulation layer and the data driving circuit. The adhesive layer can include a conductive ball and an adhesive.

According to example embodiments of the disclosure, the conductive ball can include a core and a shell surrounding the core, wherein, the core is formed of resin, and the shell is formed of a metal material.

According to example embodiments of the disclosure, the conductive ball can include a core, wherein, the core is formed of a metal material.

According to example embodiments of the disclosure, provided is a display panel provided with a display area and a non-display area, the display panel comprising: a first pad area disposed in the non-display area; an align mark disposed to be spaced apart from the first pad area; and a structure disposed adjacent to the align mark.

According to example embodiments of the disclosure, provided is a display panel, comprising: a plurality of insulation layers; a pad electrode disposed among the plurality of insulation layers and including a plurality of metal layers; an align mark disposed among the plurality of insulation layers and adjacent to the pad electrode; and a structure disposed among the plurality of insulation layers and including a plurality of metal layers, wherein the structure is disposed between the pad electrode and the align mark.

According to example embodiments of the disclosure, there can be provided a display device with enhanced reliability.

According to example embodiments of the disclosure, there can be provided a display device capable of preventing or minimizing cracks from occurring or propagating in the display panel by providing a structure in an insulation layer of the display panel.

According to example embodiments of the disclosure, there can be provided a display device with enhanced anti-moisture permeability by preventing or minimizing cracks from occurring or propagating in the display panel.

According to example embodiments of the disclosure, there can be provided a display device capable of preventing or minimizing damage to various lines by preventing or minimizing cracks from occurring or propagating in the display panel.

According to example embodiments of the disclosure, there can be provided a display device capable of low power consumption by enhancing the lifetime of the display device by preventing or minimizing cracks from occurring or propagating in the display panel.

A display device according to various example embodiments of the disclosure can be applied to mobile devices, video phones, smart watches, watch phones, wearable devices, foldable devices, rollable devices, bendable devices, flexible devices, curved devices, slidable devices, transformable devices, electronic notebooks, electronic books, portable multimedia players (PMPs), personal digital assistants (PDAs), MP3 players, mobile medical devices, desktop PCs, laptop PCs, netbook computers, workstations, navigation devices, vehicle navigations, vehicle displays, vehicle devices, theater devices, theater displays, televisions, wallpaper devices, signage devices, game consoles, laptop computers, monitors, cameras, camcorders, and home appliances.

The above description has been presented to enable any person skilled in the art to make and use the technical idea of the disclosure, and has been provided in the context of a particular application and its requirements. Various modifications, additions and substitutions to the described example embodiments will be readily apparent to those skilled in the art, and the general principles defined herein can be applied to other example embodiments and applications without departing from the spirit and scope of the disclosure. The above description and the accompanying drawings provide an example of the technical idea of the disclosure for illustrative purposes only. That is, the disclosed example embodiments are intended to illustrate the scope of the technical idea of the disclosure.

What is claimed:

1. A display device, comprising:
a substrate including a display area and a non-display area;
a first pad area disposed in the non-display area;
an align mark disposed to be spaced apart from the first pad area; and
a structure disposed adjacent to the align mark.

2. The display device of claim 1, wherein the structure surrounds the align mark and is continuously disposed.

3. The display device of claim 1, wherein the structure surrounds the align mark and is disposed to be disconnected.

4. The display device of claim 1, wherein the structure includes:
a main structure disposed to surround the align mark; and
a sub structure disposed to surround the align mark.

5. The display device of claim 4, wherein the sub structure is disposed inside the main structure.

6. The display device of claim 4, wherein the sub structure is disposed outside the main structure.

7. The display device of claim 1, wherein the first pad area includes a first sub pad area and a second sub pad area, and
wherein the first sub pad area is disposed between the display area and the second sub pad area.

8. The display device of claim 7, wherein the align mark includes a first align mark disposed to be spaced apart from the first sub pad area, and
wherein the structure includes a first structure disposed adjacent to the first align mark.

9. The display device of claim 8, wherein the align mark further includes a second align mark disposed to be spaced apart from the second sub pad area, and
wherein the structure further includes a second structure disposed adjacent to the second align mark.

10. The display device of claim 9, wherein the first structure includes:
a first main structure disposed to surround the first align mark; and
a first sub structure disposed to surround the first align mark, and
wherein the second structure includes:
a second main structure disposed to surround the second align mark; and
a second sub structure disposed to surround the second align mark.

11. The display device of claim 10, wherein the first sub structure is disposed inside the first main structure, and the second sub structure is disposed outside the second main structure.

12. The display device of claim 10, wherein the first sub structure is disposed outside the first main structure, and the second sub structure is disposed inside the second main structure.

13. The display device of claim 9, wherein the align mark further includes a third align mark disposed between the first align mark and the second align mark, and wherein the second structure is disposed adjacent to the third align mark.

14. The display device of claim 13, wherein the second structure is disposed to surround the second align mark and the third align mark.

15. The display device of claim 1, further comprising a pad electrode disposed in the first pad area,
wherein a portion of the structure is disposed between the pad electrode and the align mark.

16. The display device of claim 15, wherein the pad electrode includes a plurality of pad electrodes disposed in a plurality of rows,
wherein the align mark is disposed to be spaced apart from an outermost pad electrode disposed at an end of at least one of the plurality of rows, and
wherein a portion of the structure is disposed between the outermost pad electrode and the align mark.

17. The display device of claim 1, further comprising a data driving circuit disposed in the first pad area,
wherein the data driving circuit is disposed to overlap at least a portion of the structure, the align mark, and the first pad area.

18. The display device of claim 1, further comprising a second pad area disposed in the non-display area,
wherein the first pad area is disposed between the display area and the second pad area.

19. A display device, comprising:
a substrate including a display area and a non-display area;
a plurality of insulation layers disposed on the substrate;
a pad electrode disposed on the substrate and including a plurality of metal layers;
an align mark disposed on the substrate and adjacent to the pad electrode; and
a structure disposed on the substrate and including a plurality of metal layers,
wherein the structure is disposed between the pad electrode and the align mark.

20. The display device of claim 19, wherein the plurality of metal layers included in the pad electrode include a first metal layer, a second metal layer, and a third metal layer.

21. The display device of claim 20, wherein the structure includes a fourth metal layer, a fifth metal layer, a sixth metal layer, and a seventh metal layer.

22. The display device of claim 21, wherein in the align mark, an eighth metal layer and a first layer are disposed, and the first layer is disposed to cover the eighth metal layer.

23. The display device of claim 22, wherein the eighth metal layer is formed with a same material as the first metal layer or the second metal layer at a same time.

24. The display device of claim 22, wherein the plurality of insulation layers include:
a first insulation layer disposed on the substrate;
a second insulation layer disposed on the first insulation layer;
a third insulation layer disposed on the second insulation layer;
a fourth insulation layer disposed on the third insulation layer; and
a fifth insulation layer disposed on the fourth insulation layer,
wherein the pad electrode is disposed in an area where a portion of the fourth and fifth insulation layers is removed, and
wherein the structure is disposed in an area where a portion of the first to fifth insulation layers is removed.

25. The display device of claim 24, further comprising a link line positioned in an area overlapping the pad electrode and positioned between the first insulation layer and the second insulation layer.

26. The display device of claim 19, wherein the structure is in an electrically floated state, or wherein a thickness of the structure is larger than a thickness of the align mark and is not larger than a thickness of the pad electrode.

27. The display device of claim 26, wherein the thickness of the structure corresponds to the thickness of the pad electrode.

28. The display device of claim 19, further comprising a data driving circuit disposed on the insulation layer,
wherein the data driving circuit includes a first bump electrically connected to the pad electrode.

29. The display device of claim 28, wherein the data driving circuit further includes:
a second bump disposed to overlap the align mark; and
a third bump disposed to overlap the structure.

30. The display device of claim 28, further comprising an adhesive layer disposed between the insulation layer and the data driving circuit,
wherein the adhesive layer includes a conductive ball and an adhesive.

31. The display device of claim 30, wherein the conductive ball includes a core and a shell surrounding the core, and
wherein, the core is formed of resin, and the shell is formed of a metal material.

32. The display device of claim 30, wherein the conductive ball includes a core, and
wherein the core is formed of a metal material.

33. A display panel provided with a display area and a non-display area, the display panel comprising:
a first pad area disposed in the non-display area;
an align mark disposed to be spaced apart from the first pad area; and
a structure disposed adjacent to the align mark.

34. A display panel, comprising:
a plurality of insulation layers;
a pad electrode disposed among the plurality of insulation layers and including a plurality of metal layers;
an align mark disposed among the plurality of insulation layers and adjacent to the pad electrode; and
a structure disposed among the plurality of insulation layers and including a plurality of metal layers,
wherein the structure is disposed between the pad electrode and the align mark.

35. A vehicle, comprising:
at least one display device according to claim 1.
